(19) United States
(12) Patent Application Publication
(10) Pub. No.: US 2015/0171372 A1
(43) Pub. Date: Jun. 18, 2015

(54) FLUORESCENT MATERIAL, FLUORESCENT COATING MATERIAL, PHOSPHOR SUBSTRATE, ELECTRONIC APPARATUS, AND LED PACKAGE

(71) Applicant: Sharp Kabushiki Kaisha, Osaka-shi (JP)

(72) Inventors: Akiko Iwata, Osaka (JP); Mitsuhiro Koden, Osaka (JP); Yoshimasa Fujita, Osaka (JP)

(73) Assignee: SHARP KABUSHIKI KAISHA, Osaka-shi (JP)

(21) Appl. No.: 14/411,372

(22) PCT Filed: May 17, 2013
(86) PCT No.: PCT/JP2013/063793

§ 371 Date: Dec. 24, 2014

(30) Foreign Application Priority Data
Jul. 4, 2012 (JP) 2012-150446

(51) Int. Cl. H01L 51/52; H01L 27/32; H01L 33/58; H01L 27/15

(52) U.S. Cl. CPC H01L 51/5268; H01L 27/153; H01L 27/3211; H01L 33/58

(57) ABSTRACT

A fluorescent material is configured with a phosphor containing material, and fine particles dispersed in the phosphor containing material. The fine particles have a refractive index lower than that of the phosphor, and external shapes of the fine particles may be various shapes such as a spherical shape, a rectangular parallelepiped shape, a cone shape, a trigonal pyramid shape, or an indefinite form. Further, the fine particles 12 of a plurality of different shapes may be mixed and dispersed in the phosphor containing material.

### TECHNICAL FIELD

The invention relates to a fluorescent material, a fluorescent coating material, a phosphor substrate, an electronic apparatus, and an LED package that can enhance light extraction efficiency.

This patent application claims the benefit of priority of Japanese Patent Application No. 2012-150446 filed in Japan on Jul. 4, 2012, the contents of which are herein incorporated by reference.

### BACKGROUND ART

Recently, demands for a high-performance display to be mounted in a television, a personal computer, an information terminal apparatus, and the like have increased, and various types of display devices such as cathode ray tube displays, liquid crystal displays, plasma displays, and organic EL displays have been researched and developed. Among them, since the liquid crystal display is thin and light, it occupies the majority of the current display market. However, compared with the cathode ray tube display in the related art, the viewing angle is narrow, and the image recognition properties in the oblique direction are not good. In the liquid crystal display device, as a method of enhancing the performance at a viewing angle, a method of displaying colors by disposing a phosphor and a scatterer on the front surface of the liquid crystal display device is disclosed in which a portion of blue light from the polarization collimating light source is used for blue display, and a color of a portion thereof is converted into red and green using phosphors (for example, PTLs 1 and 2).

Compared with the liquid crystal display that displays full color with a color filter system which has recently been widely used, in a liquid crystal display according to a method of converting colors of the light from an excitation light source with a phosphor, the performance at a viewing angle is improved, light loss is low, and high luminance can be realized with low power consumption.

The organic EL display is a display device having excellent display performance of high contrast, a wide viewing angle, and fast response speed. However, in order to realize the full color display, patterning of an RGB luminous layer using mask evaporation should be performed. Therefore, it is difficult to cause the display to be improved in definition and to be increased in size.

In order to solve these, a method of using a single color organic EL element as an excitation light source, and causing RGB phosphors to emit light is disclosed (for example, see PTL 3). In this case, since the organic EL layer may be a single color, it is possible to cause the display to be improved in definition and to be increased in size at low cost.

In a display that causes the RGB phosphors to emit light by using the excitation light source, when light emitted from a color conversion layer is extracted to the outside via a transparent substrate such as a glass substrate, the light extraction efficiency can be calculated by Snell's law. In Snell's law, as illustrated in FIG. 20, when light proceeds from a medium having a refractive index n1 to another medium having a refractive index n2, between an incidence angle θ1 and a refraction angle θ2, a relationship of n1×sin θ1=n2×sin θ2 is established.

The incidence angle θ1=sin⁻¹(n2/n1) that satisfies θ2=90° when n1>n2 is known as a critical angle. If the incidence angle is more than the critical angle, light is totally reflected on an interface between media. Therefore, in the phosphor in which light is isotropically emitted, the light incident on the interface at an angle more than the critical angle is totally reflected, and the light cannot be incident on an adjacent layer. The light that cannot be incident on the adjacent layer is completely reflected repeatedly in the layer so as to be trapped therein.

For example, when the light is extracted into the air in which n2=1.0 through glass in which n1=1.5, the critical angle θ1 becomes 41.8°, and only light that is incident on the interface between n1 and n2 at θ1<41.8° can be extracted through the glass. Accordingly, the efficiency of extracting light to the outside becomes substantially less than 20%, which is considered to be quite a low level.

In order to improve the efficiency of extracting light to the outside of the substrate, a method of decreasing a refractive index of a light emitting portion, a method of providing a low refractive index layer between the light emitting portion and the transparent substrate for extracting light, or a method of providing a low refractive index layer on the light extraction surface side of the transparent substrate is effective. As an example of providing the low refractive index layer, a method of inserting an air space between the organic EL element functioning portion and the transparent substrate (for example, see PTL 4) and a method of enhancing light utilization efficiency by converting the color of blue light emitted by the organic EL element using the phosphor layer and providing the low refractive index layer on the light extraction surface side of the transparent substrate (for example, see PTL 5) are known. Also, a method of introducing a hollow silica layer having a low refractive index between the phosphor layer and the substrate has been suggested (for example, see PTL 6). Further, a method of enhancing the light extraction efficiency by using a color converting filter having a refractive index of equal to or higher than 1.30 and equal to or lower than 1.48 has also been suggested (for example, see PTL 7).

### CITATION LIST

### Patent Literature

PTL 1: Japanese Unexamined Patent Application Publication No. 2000-131683

PTL 2: Japanese Unexamined Patent Application Publication No. 62-194227

PTL 3: Japanese Unexamined Patent Application Publication No. 03-152897

PTL 4: Japanese Unexamined Patent Application Publication No. 2003-045642

PTL 5: Japanese Unexamined Patent Application Publication No. 2007-207655

PTL 6: Japanese Unexamined Patent Application Publication No. 2003-216601

PTL 7: Japanese Unexamined Patent Application Publication No. 2006-190633

### SUMMARY OF INVENTION

### Technical Problem

In each of the methods of enhancing the light extraction efficiency disclosed in PTLs 4 to 7 described above, however, a new layer such as the low refractive index layer is inserted into an already existing layer configuration, or a color converting filter is used. Therefore, the layer configuration becomes complicated, and the thickness thereof increases, so that the thickness may not be reduced.

Some aspects of the invention are provided in view of the circumstances described above, and an object of the invention is to provide a fluorescent material, a fluorescent coating material, a phosphor substrate, an electronic apparatus, and an LED package that can enhance the light extraction efficiency without causing the structure to be complicated.

### Solution to Problem

In order to solve the problems described above, some aspects of the invention provide a fluorescent material, a fluorescent coating material, a phosphor substrate, an electronic apparatus, and an LED package as follows.

That is, a fluorescent material according to an aspect of the invention includes at least a phosphor and a fine particle.

The fine particle may have a refractive index lower than that of the phosphor.

The refractive index of the fine particle may be higher than 1.0 and lower than 1.3.

The phosphor may be a perylene-based dye or a coumarin-based dye.

The particle diameter of the fine particle may be equal to or more than 5 nm and equal to or less than 300 nm.

The fine particle may be a porous particle or a hollow particle.

An outer shell of the hollow particle may have a thickness equal to or more than 5% and equal to or less than 80% of the particle diameter of the hollow particle.

The ratio of a volume of the fine particle in a solid portion of the entire fluorescent material may be equal to or more than 10% and equal to or less than 80%.

A fluorescent coating material according to another aspect of the invention includes the fluorescent material according to any of the respective items above.

A phosphor substrate according to still another aspect of the invention includes the fluorescent material according to any of the respective items above.

The phosphor substrate according to still another aspect of the invention may include at least a light-transmitting substrate; the phosphor; and the fine particle having a refractive index lower than those of the substrate and the phosphor.

The phosphor substrate according to still another aspect of the invention may further include a color filter between the phosphor and the substrate that forms a fluorescence emitting side.

An electronic apparatus according to still another aspect of the invention uses the phosphor substrate according to any of the respective items above.

Further, the electronic apparatus according to still another aspect of the invention may include the phosphor substrate according to any of the respective items above; and an excitation light source that excites the phosphor to generate fluorescence.

The excitation light source may be an organic electroluminescence element that emits ultraviolet light or blue light.

The excitation light source may be an ultraviolet light LED or a blue light LED.

The electronic apparatus according to still another aspect of the invention may further include a liquid crystal layer that is provided between the excitation light source and the phosphor substrate and that controls excitation light incident on the phosphor substrate from the excitation light source.

The electronic apparatus according to still another aspect of the invention may further include a band pass filter that is provided between the excitation light source and the phosphor substrate, transmits only light having a specific wavelength, and reflects light other than the light having the specific wavelength.

The phosphor substrate may be partitioned into a plurality of pixels and has at least a red pixel that emits red light and a green pixel that emits green light.

At least a portion of side surfaces of one or both of the red pixel and the green pixel may be surrounded by partition walls having light scattering properties.

An LED package according to still another aspect of the invention includes the fluorescent material according to any of the respective items described above.

### Advantageous Effects of Invention

According to some aspects of the invention, it is possible to provide a fluorescent material, a fluorescent coating material, a phosphor substrate, an electronic apparatus, and an LED package that can enhance light extraction efficiency without causing the structure to be complicated.

### BRIEF DESCRIPTION OF DRAWINGS

FIG. 1A is a diagram schematically illustrating a fluorescent material according to an embodiment of the invention.

FIG. 1B is a diagram schematically illustrating a fluorescent material according to an embodiment of the invention.

FIG. 1C is a diagram schematically illustrating a fluorescent material according to an embodiment of the invention.

FIG. 1D is a diagram schematically illustrating a fluorescent material according to an embodiment of the invention.

FIG. 1E is a diagram schematically illustrating a fluorescent material according to an embodiment of the invention.

FIG. 1F is a diagram schematically illustrating a fluorescent material according to an embodiment of the invention.

FIG. 2A is a diagram schematically illustrating a fluorescent material according to an embodiment of the invention.

FIG. 2B is a diagram schematically illustrating a fluorescent material according to an embodiment of the invention.

FIG. 2C is a diagram schematically illustrating a fluorescent material according to an embodiment of the invention.

FIG. 2D is a diagram schematically illustrating a fluorescent material according to an embodiment of the invention.

FIG. 3 is a graph illustrating light resistance evaluation results.

FIG. 4 is a cross-sectional view illustrating a display device according to a first embodiment of the invention.

FIG. 5 is a cross-sectional view illustrating a phosphor substrate according to the invention.

FIG. 6 is a cross-sectional view illustrating a display device according to a second embodiment of the invention.

FIG. 7 is a cross-sectional view illustrating a display device according to a third embodiment of the invention.

FIG. 8 is a cross-sectional view illustrating an example of an LED (light source).

FIG. 9 is a cross-sectional view illustrating an organic EL element (light source).

FIG. 10 is a cross-sectional view illustrating an inorganic EL element (light source).

FIG. 11 is a cross-sectional view illustrating a display device according to a fourth embodiment of the invention.

FIG. 12 is a cross-sectional view illustrating a display device according to a fifth embodiment of the invention.

FIG. 13A is a diagram schematically illustrating an example of an electronic apparatus.

FIG. 13B is a diagram schematically illustrating an example of the electronic apparatus.

FIG. 14A is a diagram schematically illustrating an example of the electronic apparatus.

FIG. 14B is a diagram schematically illustrating an example of the electronic apparatus.

FIG. 15A is a diagram schematically illustrating an example of the electronic apparatus.

FIG. 15B is a diagram schematically illustrating an example of the electronic apparatus.

FIG. 16 is a diagram schematically illustrating an example of the electronic apparatus.

FIG. 17 is a cross-sectional view illustrating an LED package according to an embodiment of the invention.

FIG. 18A is a cross-sectional view illustrating a forming process according to a comparative example.

FIG. 18B is a cross-sectional view illustrating a forming process according to the comparative example.

FIG. 18C is a cross-sectional view illustrating a display device according to the comparative example.

FIG. 18D is a cross-sectional view illustrating a forming process according to the comparative example.

FIG. 18E is a cross-sectional view illustrating a forming process according to the comparative example.

FIG. 19 is a cross-sectional view illustrating a display device according to a comparative example.

FIG. 20 is an explanatory diagram illustrating refraction on a fluorescence emitting surface.

FIG. 21 is a diagram illustrating a relationship between low refractive index fine particles added to a phosphor layer and apparent brightness evaluation results.

### DESCRIPTION OF EMBODIMENTS

Hereinafter, manufacturing methods of a fluorescent material, a fluorescent coating material, a phosphor substrate, an electronic apparatus, and an LED package according to embodiments will be described with reference to the drawings. Further, the embodiments below are described in detail for better understanding of a gist of an aspect of the invention, and if it is not particularly stated, the invention is not limited to the aspects of the invention. In addition, in the drawings described herein, for convenience, portions which become main parts are enlarged in some cases for better understanding of characteristics of the embodiments, and ratios of dimensions between the respective components are not necessarily same as the real ones.

Fluorescent Material

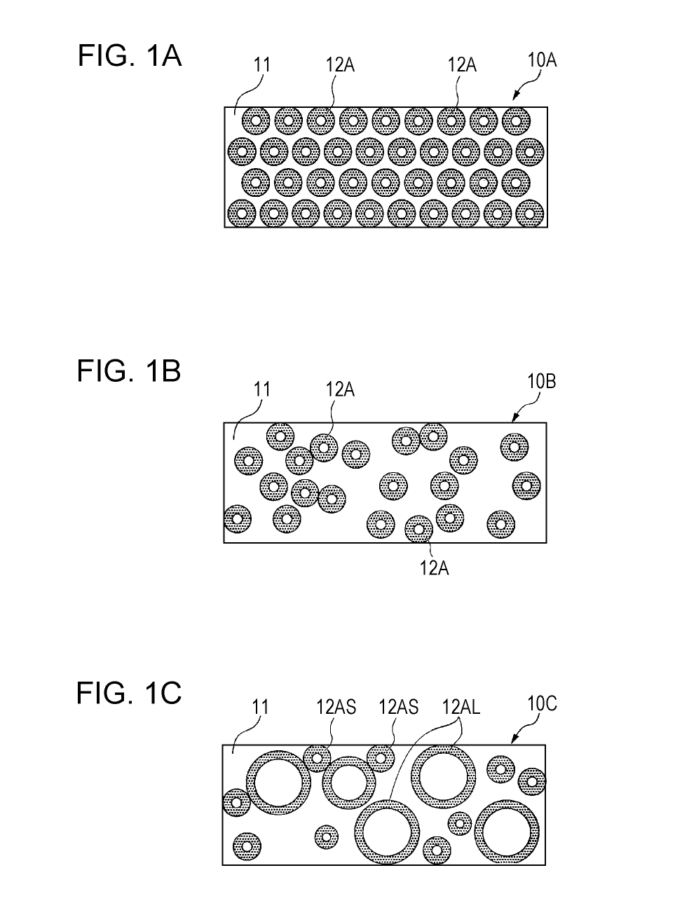

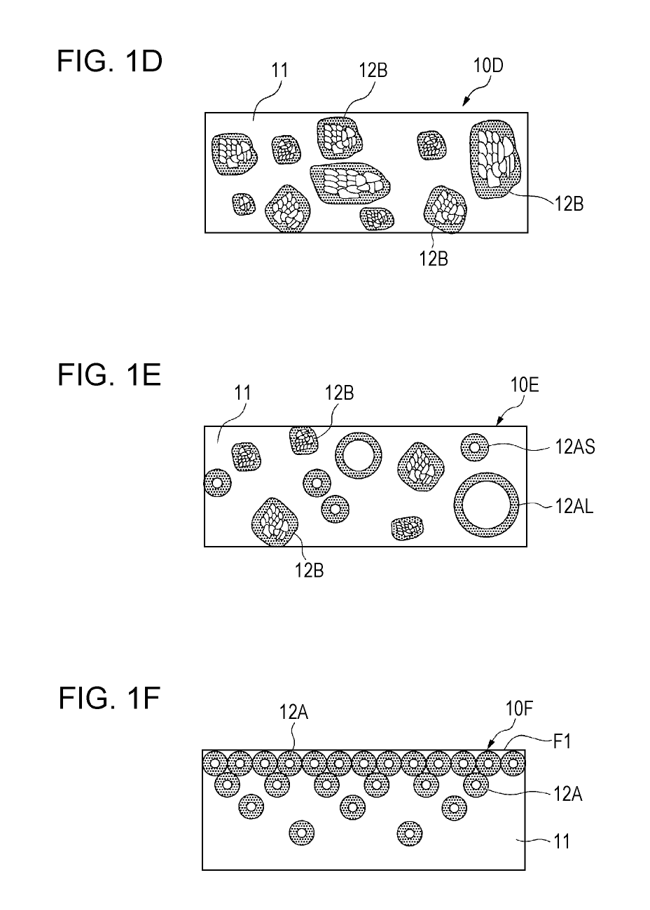

The fluorescent material is configured of at least phosphors and fine particles, and may further include a binder resin. FIG. 1A to FIG. 2D are diagrams schematically illustrating a fluorescent material according to the embodiment. A fluorescent material 10 includes a phosphor containing material 11 in which the phosphor is dissolved and dispersed in the binder resin, and fine particles 12 which are dispersed in the phosphor containing material 11. External shapes of the fine particles 12 may be various shapes such as a spherical shape, a rectangular parallelepiped shape, a cone shape, a trigonal pyramid shape, a scale shape, or an indefinite form. Further, the fine particles 12 having different shapes may be mixed and dispersed in the phosphor containing material 11.

It is preferred that the fine particles 12 be configured with a material having a lower refractive index than the phosphor containing material 11. For example, the fine particles 12 may use a material having a refractive index in the range of higher than 1.0 and lower than 1.3. It is preferable that the particle diameter (average particle diameter) of the fine particles be, for example, in the range of equal to or more than 5 nm, and equal to or less than 300 nm.

The fine particles 12 have various external shapes as described above, and only need to be, for example, porous particles or hollow particles. If hollow particles are used as the fine particles 12, the thicknesses of outer shells only need to be, for example, in the range of equal to or more than 5%, and equal to or less than 80% of the particle diameters of the hollow particles.

In the fluorescent material 10, the phosphor containing material 11 and the fine particles 12 may be distributed so that the ratio of a volume of the fine particles 12 in a solid portion of the fluorescent material 10 is in the range of equal to or more than 10% and equal to or less than 80%.

A fluorescent material 10A according to the embodiment illustrated in FIG. 1A is an example in which spherical and hollow fine particles 12A are evenly dispersed in the phosphor containing material 11.

A fluorescent material 10B according to the embodiment illustrated in FIG. 1B is an example in which the spherical and hollow fine particles 12A are unevenly dispersed in the phosphor containing material 11.

A fluorescent material 10C according to the embodiment illustrated in FIG. 1C is an example in which spherical and hollow fine particles 12AL and 12AS having different diameters are unevenly dispersed in the phosphor containing material 11.

A fluorescent material 10D according to the embodiment illustrated in FIG. 1D is an example in which porous fine particles 12B are unevenly dispersed in the phosphor containing material 11.

A fluorescent material 10E according to the embodiment illustrated in FIG. 1E is an example in which the porous fine particles 12B and the spherical and hollow fine particles 12AL and 12AS having different diameters are unevenly dispersed in the phosphor containing material 11.

A fluorescent material 10F according to the embodiment illustrated in FIG. 1F is an example in which the spherical and hollow fine particles 12A are dispersed in the phosphor containing material 11 in a biased manner so as to be more dispersed on a light emitting surface side (fluorescence emitting surface side) F1 of the fluorescent material 10F.

A fluorescent material 10G according to the embodiment illustrated in FIG. 2A is an example in which the spherical and hollow fine particles 12A, the trigonal pyramid-shaped and hollow fine particles 12C, and rectangular parallelepiped-shaped and hollow fine particles 12D are unevenly dispersed in the phosphor containing material 11.

A fluorescent material 10H according to the embodiment illustrated in FIG. 2B is an example in which the spherical and hollow fine particles 12A are dispersed in the phosphor containing material 11 in a biased manner so as to be more dispersed on a light incident surface side F2 of the fluorescent material 10F.

A fluorescent material 101 according to the embodiment illustrated in FIG. 2C is an example in which the spherical and hollow fine particles 12A are dispersed in the phosphor containing material 11 in a biased manner so as to be more dispersed on the light emitting surface side (fluorescence emitting surface side) F1 and the light incident surface side F2 of the fluorescent material 10F.

A fluorescent material 10J according to the embodiment illustrated in FIG. 2D is an example in which the spherical and hollow fine particles 12A are dispersed in the phosphor containing material 11 in a biased manner so as to be more dispersed in an intermediate portion between the light emitting surface side (fluorescence emitting surface side) F1 and the light incident surface side F2 of the fluorescent material 10F.

Hereinafter, detailed embodiments of phosphors and fine particles included in the fluorescent material are described.

As the phosphor according to the embodiment, known phosphors can be used. The phosphors are classified into organic phosphor materials and inorganic phosphor materials, and specific compounds are provided as examples thereof below, but the phosphor is not limited to such materials.

In addition, different fluorescent materials may be used in combination, or a hybrid phosphor of an organic phosphor and an inorganic phosphor may be used.

Further, in view of high efficiency, it is more preferable to use a material in which the absorptance of light having an excitation wavelength is high, and the internal quantum yield is high.

In the case of the organic phosphor material, examples of a blue fluorescence dye include a stilbenzene-based dye: 1,4-bis(2-methylstyryl)benzene and trans-4,4′-diphenyl stilbenzene, a coumarin-based dye: 7-hydroxy-4-methylcoumarin, 2,3,6,7-tetrohydro-11-oxo-1H,5H,11H-[1]benzopyrano[6,7,8-ij]quinolizine-10-carboxylate (coumarin 314), and 10-acetyl-2,3,6,7-tetrohydro-1H,5H,11H-[1]benzopyrano[6,7,8-ij]quinolizine-11-on (coumarin 334), and an anthracene-based dye: 9,10 bis(phenylethynyl)anthracene, and pherylene.

Examples of a green fluorescence dye include a coumarin-based dye: 2,3,5,6-1H,4H-tetrahydro-8-triflomethyl quinolizine(9,9a,1-gh)coumarin (coumarin 153), 3-(2′-benzothiazolyl)-7-diethylaminocoumarin (coumarin 6), 3-(2′-benzoimidazolyl)-7-N,N-diethylaminocoumarin (coumarin 7), 10-(benzothiazole-2-yl)-2,3,6,7-tetrohydro-1H,5H,11H-[1]benzopyrano[6,7,8-ij]quinolizine-11-one (coumarin 545), coumarin 545T, and coumarin 545P, a naphthalimido-based dye: basic yellow 51, solvent yellow 11, solvent yellow 98, solvent yellow 116, solvent yellow 43, and solvent yellow 44, a perylene-based dye: Lumogen yellow, Lumogen green, and solvent green 5, a fluorescein-based dye, an aso-based dye, a phthalocyanine-based dye, an anthraquinone-based dye, a quinacridone-based dye, an isoindolinone-based dye, a thioindigo-based dye, and a dioxazine-based dye.

Examples of a red fluorescence dye include a cyanine-based dye: 4-dicyanomethylene-2-methyl-6-(p-dimethylaminostyryl)-4H-pyran (DCM), DCM-2, and DCJTB, a pyridine-based dye: 1-ethyl-2-[4-(p-dimethylaminophenyl)-1,3-butadienyl]-pyridinium-perchlorate (pyridine 1), a xanthene-based dye: Rhodamine B, Rhodamine 6G, Rhodamine 3B, Rhodamine 101, Rhodamine 110, basic violet 11, Sulforhodamine 101, basic violet 11, and basic red 2, a perylene-based dye: Lumogen orange, Lumogen pink, Lumogen red, and solvent orange 55, an oxazine-based dye, a chrysene-based dye, a thioflavin-based dye, a pylene-based dye, an anthracene-based dye, an acridon-based dye, an acridine-based dye, a fluorene-based dye, a terphenyl-based dye, an ethen-based dye, a butadiene-based dye, a hexatriene-based dye, an oxazole-based dye, a coumarin-based dye, a stilbene-based dye, a triphenylmethane-based dye, a thiazole-based dye, a thiazine-based dye, a naphthalimido-based dye, and an anthraquinone-based dye.

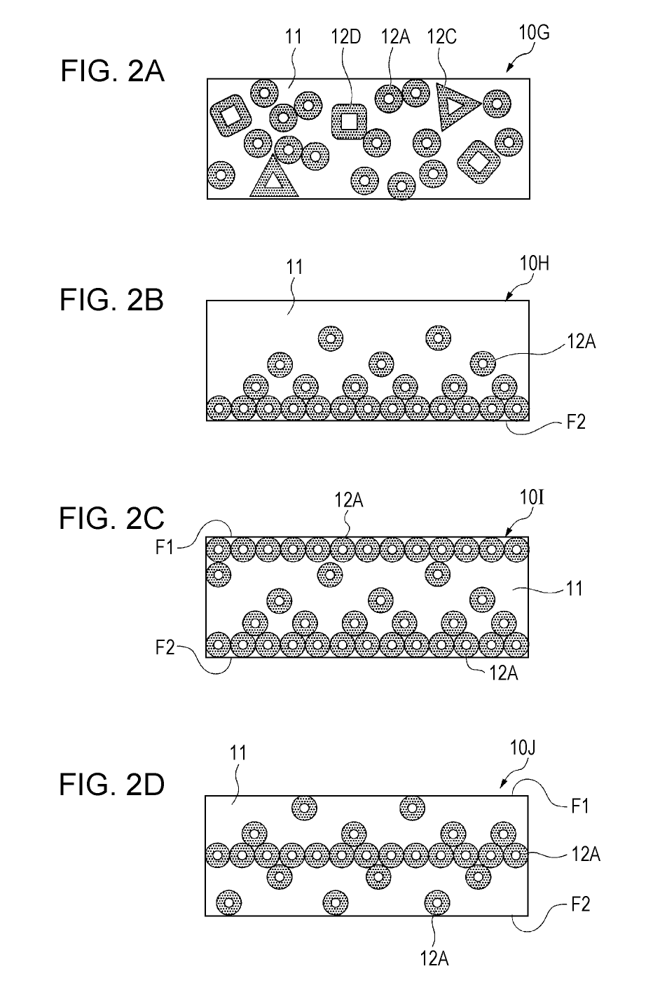

If organic phosphor materials are used as phosphors of the respective colors, it is desirable to use a dye that is difficult to be deteriorated by external light such as blue or ultraviolet backlight, sunlight, or lighting. Therefore, it is preferable to use a perylene-based dye in which light resistance is excellent and the quantum yield is high. FIG. 3 is a diagram illustrating a light resistance test result when blue light is applied to a thin film in which coumarin 6 is added to a polystyrene resin (indicated by triangles in FIG. 3), a thin film in which Lumogen yellow which is a perylene-based dye is added in the polystyrene resin (indicated by white circles in FIG. 3), and a thin film in which Lumogen red which is a perylene-based dye is added to the polystyrene resin (indicated by black circles in FIG. 3). In addition, the normalized luminance is defined as ratios of the products of the absorptances of the light having a wavelength of 450 nm when the blue light having a peak wavelength of 450 nm at illuminance of 120 W/m² is applied to the thin films including the phosphors and internal quantum yields when the thin films are excited with light at 450 nm at respective application times to the products of the absorptances of the light having the wavelength of 450 nm when the blue light having the peak wavelength of 450 nm at the illuminance of 120 W/m² is applied to the thin films including the phosphors and internal quantum yields when the thin films are excited with light of 450 nm at the time 0. In FIG. 3, it can be understood that light resistance of the thin film to which the Lumogen-based dye is added increases from one digit to two digits compared with the thin film to which coumarin 6 is added.

Further, in the case of the inorganic-based phosphor material, examples of the blue phosphor include Sr₂P₂O₇:Sn⁴⁺, Sr₄Al₁₄O₂₅:Eu²⁺, BaMgAl₁₀O₁₇:Eu²⁺, SrGa₂S₄:Ce³⁺, CaGa₂S₄:Ce³⁺, (Ba, Sr)(Mg, Mn)Al₁₀O₁₇:Eu²⁺, (Sr, Ca, Ba₂, 0 Mg)₁₀(PO₄)₆Cl₂:Eu²⁺, BaAl₂SiO₈:Eu²⁺, Sr₂P₂O₇:Eu²⁺, Sr₅ (PO₄)₃Cl:Eu²⁺, (Sr, Ca, Ba)₅(PO₄)₃Cl:Eu²⁺, BaMg₂Al₁₆O₂₇:Eu²⁺, (Ba, Ca)₅(PO₄)₃Cl:EU²⁺, Ba₃MgSi₂O₈:Eu²⁺, and Sr₃MgSi₂O₈: Eu²⁺.

Examples of the green phosphor include (BaMg)Al₁₆O₂₇:Eu²⁺, Mn²⁺, Sr₄Al₁₄O₂₅:Eu²⁺, (SrBa)Al₁₂Si₂O₈:Eu²⁺, (BaMg)₂SiO₄:Eu²⁺, Y₂SiO₅:Ce³⁺, Tb³⁺, Sr₂P₂O₇—Sr₂B₂O₅:Eu2+, (BaCaMg)₅(PO₄)₃Cl:Eu²⁺, Sr₂Si₃O₈-2SrCl₂:Eu²⁺, Zr₂SiO₄, MgAl₁₁O₁₉:Ce³⁺, Tb³⁺Ba₂SiO₄:Eu²⁺, Sr₂SiO₄:Eu²⁺, and (BaSr)SiO₄:Eu²⁺.

Examples of the red phosphor include Y₂O₂S:Eu³⁺, YAlO₃:Eu³⁺, Ca₂Y₂(SiO₄)₆: Eu³⁺, LiY₉(SiO₄)₆O₂:EU³⁺, YVO₄:EU³⁺, CaS:Eu³⁺, Gd₂O₃:Eu³⁺, Gd₂O₂S:Eu³⁺, Y(P,V)O₄:Eu³⁺, Mg₄GeO_{5.5}F:Mn⁴⁺, Mg₄GeO⁶:Mn⁴⁺, K₅Eu_{2.5}(WO₄)_{6.25}, Na₅Eu_{2.5}(WO₄)_{6.25}, K₅Eu_{2.5}(MoO₄)_{6.25}, and Na₅Eu_{2.5}(MoO₄)_{6.25}.

Further, the inorganic phosphors may be subjected to a surface modifying treatment, if necessary. Examples of the surface modifying treatment include a chemical treatment using a silane coupling agent or the like, a physical treatment performed by adding fine particles of a submicron order or the like, and a combination of both. In view of the stability against deterioration caused by excitation light and the deterioration caused by light emission, it is preferable to use an inorganic material. Further, when the inorganic material is used, it is preferable that the average particle diameter (d₅₀) be 0.5 μm to 50 μm. If the average particle diameter is less than 1 μm, the light emission efficiency of the phosphors may rapidly decrease. Also, if the average particle diameter is equal to or more than 50 μm, it may be difficult to perform patterning at high resolution.

Fine Particle Material

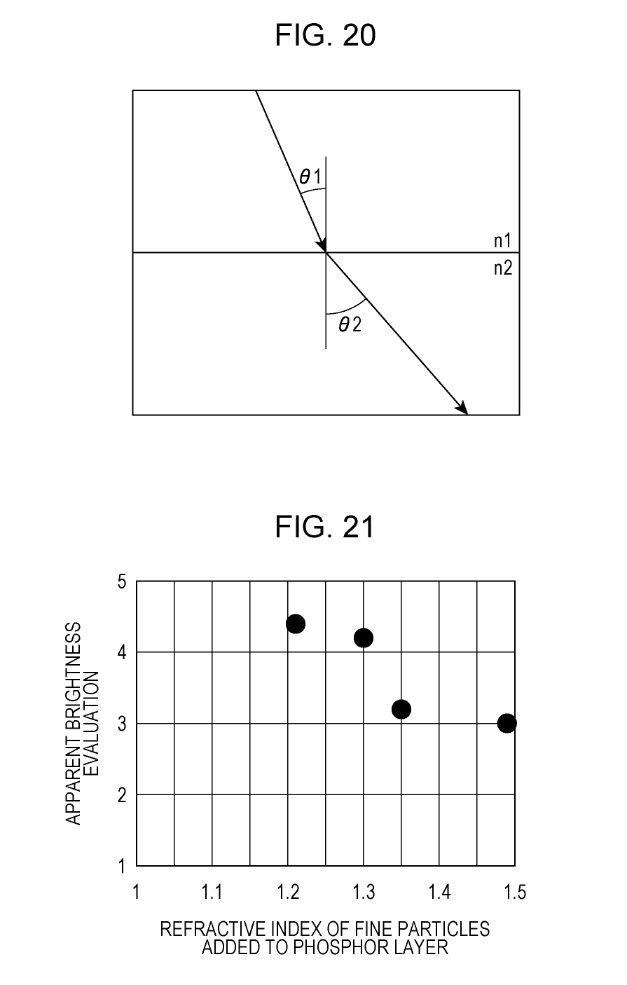

In order to control the refractive index of the phosphor layer, fine particles are dispersed and mixed in a phosphor. In order to enhance the efficiency of extracting light to the outside, it is effective to mix fine particles having a lower refractive index than the phosphor into the phosphor. FIG. 21 is a diagram illustrating a relationship between low refractive index fine particles added to the phosphor layer and apparent brightness evaluation results. A phosphor layer is formed by performing spin coating with a phosphor solution obtained by adding fine particles having various refractive indexes to a green phosphor having a refractive index of 1.5 on a glass that forms a green color filter. Kinds and refractive indexes of fine particles and volume fractions of the fine particles in the phosphor layer are presented in Table 1. After the phosphor layer is dried, the blue LED is emitted from the phosphor layer side, and brightness on the glass side is visually evaluated. Brightness is visually evaluated in 5 steps by a plurality of evaluators (brightness when fine particles are not added is set to be 3, and the greater number means the more brightness). The results are averaged, and it is understood that if the refractive index of the added fine particles is equal to or higher than 1.3, it is seen that the brightness rapidly decreases in the apparent evaluation as illustrated in FIG. 21. Therefore, it is preferable that the fine particles added to the phosphor layer have a refractive index equal to or higher than 1.0 and equal to or lower than 1.3. Further, since the vacuum refractive index is 1.0, no materials have a refractive index lower than 1.0. As described above, adding fine particles having a low refractive index to the phosphor layer is effective to enhance the light extraction efficiency.

TABLE 1

| | | | | | Volume | |
|---|---|---|---|---|---|---|
| | | | | | fractions of | |
| | | | | Refrac- | fine particles | Apparent |
| | | | Fine | tive | in phosphor | brightness |
| | Phosphor | Polymer | particles | index | layer (%) | evaluation |
| 1 | Coumarin | PMMA | Hollow | 1.21 | 80 | 4.4 |
| | 545T | | silica | | | |
| 2 | | | Hollow | 1.30 | 80 | 4.2 |
| | | | silica | | | |
| 3 | | | Hollow | 1.35 | 80 | 3.3 |
| | | | silica | | | |
| 4 | | | PMMA | 1.49 | 80 | 3.0 |

Examples of fine particles having a refractive index of equal to or lower than 1.3 include a fluorine-based polymer, porous fine particles such as porous silica, or hollow fine particles such as hollow silica which have low refractive indexes, or a combination thereof.

The porous fine particles refer to fine particles having many pores.

The hollow fine particles refer to fine particles having hollow structures (balloon structures) inside.

Examples of porous or hollow fine particles include inorganic particles made of silica, titanium dioxide, zinc sulfide, cadmium sulfide, or the like or organic particles made of resins.

In order to enhance the dispersibility of the fine particles, organic-inorganic hybrid type materials in which, for example, the hydrocarbon-based polymers are combined with the silica on the surface of the hollow silica may be used.

Here, the refractive indexes of the porous particles or the hollow particles refer to the refractive indexes of the entire surface of the hollow particles. For convenience, values expressed by Equation 1 described below are employed as the refractive indexes of the porous particles and the hollow particles. In Equation (1), nₚ is the refractive index of the hollow particles, nₛ is the refractive index of materials in portions other than cavities of porous or hollow particles, n_{c} is the refractive index of cavity portions of porous or hollow particles, and x is the volume fraction of portions other than the cavities in the porous or hollow particles.

nₚ=x·nₛ+(1−x)·nₚ (1)

The hollow fine particle is a particle in which a cavity is formed in one fine particle, and for example, with respect to the hollow silica particle, the cavity in the hollow silica particle is covered with silicon oxide. Therefore, the refractive index of the hollow fine particles is lower than that of typical non-hollow particles because of the air in the cavity, and for example, the typical silica particles have a refractive index of 1.46, but the refractive index of the hollow silica particles may be equal to or lower than 1.3.

The hollow particles can be manufactured, for example, by suitably using a manufacturing method disclosed in JP-A-2001-233611.

If these fine particles are porous silica or hollow silica, the gas in the particles may be inert gas instead of the air or nitrogen.

If the fine particles are hollow particles, as the porosity increases, the refractive index can decrease. Therefore, the light extraction efficiency can be improved. However, it is required to cause outer shells to be thin in order to enhance the porosity, and therefore it is difficult to manufacture the particles. Therefore, it is preferable that the thickness of the outer shell be equal to or more than 10% of the particle diameter so that the porosity becomes equal to or less than 73%. Meanwhile, if the thickness of the outer shell is equal to or more than 80% of the particle diameter, the porosity becomes equal to or less than 8%. Therefore, the effect of lowering the refractive index may not be obtained.

It is preferable that the average particle diameter of the fine particles range from 5 nm to 300 nm. If the average particle diameter is more than 300 nm, light scatters by Mie scattering or geometric optical scattering, the light looks white, and the transparency decreases. Further, if the average particle diameter is smaller than 5 nm, fine particles cohere with each other, and may not be evenly dispersed in the phosphor layer. In order to enhance transparency and dispersibility, it is more preferable that the average particle diameter range from 10 nm to 50 nm.

The volume of the fine particles may be smaller than 90% of the volume of the phosphor layer. If the volume of the fine particles becomes equal to or more than 90%, it becomes difficult to form the phosphor layer into a uniform thin film. Further, if the volume of the fine particles is equal to or less than 10% of the volume of the phosphor layer, since the volume of the hollow portion in the phosphor layer is not sufficiently great, the effect of lowering the refractive index may not be obtained. In order to form the phosphor layer into a uniform thin film, and to sufficiently obtain the effect of lowering the refractive index, it is preferable that the volume of the fine particles be equal to or more than 50%, and equal to or less than 80% of the volume of the phosphor layer.

It is preferable that the binder resin material be a transparent resin. Examples of the resin material include an acryl resin, a melamine resin, a polyester resin, a polyurethane resin, an alkyd resin, an epoxy resin, a butyral resin, a polysilicon resin, a polyamide resin, a polyimide resin, a melanin resin, a phenol resin, polyvinyl alcohol, polyvinyl hydrin, hydroxyethyl cellulose, carboxymethyl cellulose, an aromatic sulfonamide resin, a urea resin, a benzoguanamine resin, triacetyl cellulose (TAC), polyether sulfone, polyether ketone, nylon, polystyrene, melamine beads, polycarbonate, polyvinyl chloride, polyvinylidene chloride, polyvinyl acetate, polyethylene, polymethyl methacrylate, poly MBS, medium density polyethylene, high density polyethylene, tetrafluoroethylene, polychloro trifluoroethylene, and polytetrafluoroethylene.

Fluorescent Coating Material

When the fluorescent material described above is formed on a substrate by a wet process in order to obtain a phosphor substrate, it is preferable to use a fluorescent coating material obtained by causing the fluorescent material to be coating liquid. The fluorescent coating material according to the embodiment can be obtained by using the fluorescent material described above and adding the appropriate solvent and the appropriate binder resin so that the fluorescent material is dissolved or dispersed. Further, it is possible to add further compositions in order to adjust the viscosity.

Phosphor Substrate: First Embodiment

The phosphor substrate according to the embodiment can be obtained by applying the fluorescent coating material including the fluorescent material described above on a substrate by a known wet process, for example, a coating method such as a spin coating method, a dipping method, a doctor blade method, a discharging coating method, and a spray coating method, and a printing method such as an ink jet method, a letterpress printing method, a printing intaglio method, a screen printing method, and a micro gravure coating method.

The phosphor substrate can be obtained by forming a pattern on the substrate with the fluorescent material by using a known dry process such as a resistance heating vapor deposition method, an electron beam (EB) deposition method, a molecular beam epitaxy (MBE) method, a sputtering method, or an organic Vapor Phase Deposition (OVPD) method, or a laser transferring method without causing the fluorescent material to become coating liquid such as a fluorescent coating material.

Display Device: First Embodiment

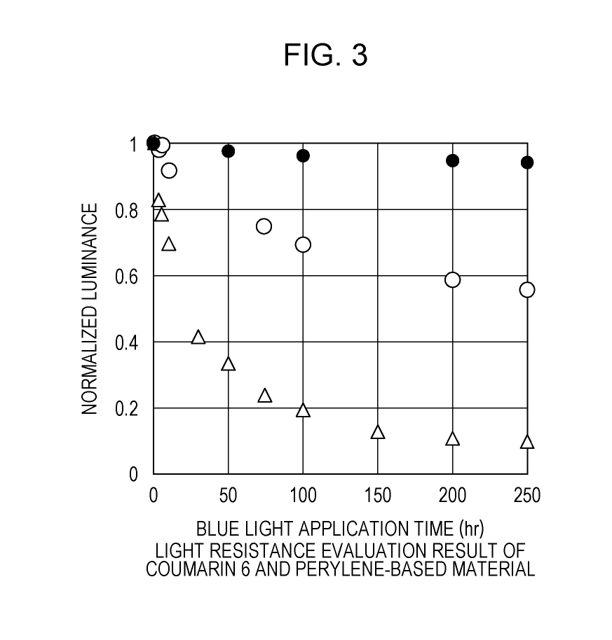

FIG. 4 is a cross-sectional view schematically illustrating the display device according to the first embodiment. Here, the cross-sectional view of FIG. 4 illustrates a cross section of a display device 100A taken along a plane surface orthogonal to the upper surface of a substrate 30. Hereinafter, the schematic view of the cross section when the display device is taken along the plane surface orthogonal to the upper surface of the substrate 30 may be referred to as the cross-sectional view of the display device.

The display device 100A according to the embodiment includes a phosphor substrate 20 and a light source substrate 21 bonded to the phosphor substrate 20 via a bonding layer 24. The phosphor substrate 20 is obtained by forming the fluorescent material according to the embodiments described above (see FIGS. 1A to 2D) on the substrate, and one pixel which is a minimum unit for configuring an image is configured by three subpixels that respectively display red, green, and blue colors. In the description below, a subpixel that displays a red color is referred to as a red subpixel PR, a subpixel that displays a green color is referred to as a green subpixel PG, and a subpixel that displays a blue color is referred to as a blue subpixel PB.

The light source substrate 21 includes a substrate 29 and light sources 22 disposed on the phosphor substrate 20 side of the substrate 29. Ultraviolet light or blue light is emitted from the light sources 22 as the excitation light L1.

The phosphor substrate 20 receives the excitation light L1 emitted from the light sources 22 to cause the red subpixel PR to generate red fluorescence L2, and cause the green subpixel PG to generate the green fluorescence L2. The blue fluorescence L2 is generated from the blue subpixel PB, or the blue light from the excitation light source is scattered by a scatterer arranged in the blue subpixel PB. Also, full color display can be performed with the respective three colors of red, green, and blue.

The phosphor substrate 20 according to the embodiment includes the substrate 30, phosphor layers 31R, 31G, and 31B, partition walls 35, and color filters 34R, 34G, and 34B. The phosphor layers 31R, 31G, and 31B are provided on the substrate 30, and generate the fluorescence L2 with the excitation light L1 incident from the upper side of the substrate 30. The partition walls 35 surround side surfaces of phosphor layers 3R, 3G, and 3B.

An excitation light incident surface 31a on which the excitation light L1 for the phosphor layers 31R, 31G, and 31B is incident is exposed by the opening portions of the partition walls 35. That is, the excitation light incident surfaces 31a are surfaces on which the excitation light L1 emitted from the light sources 22 can be incident. The excitation light L1 is converted to the fluorescence L2 by the phosphor layers 31R, 31G, and 31B, and the fluorescence L2 is emitted from emission surfaces 31b of the phosphor layers 31R, 31G, and 31B.

The phosphor layers 31R, 31G, and 31B are formed with a plurality of phosphor layers divided for each subpixel, and the plurality of phosphor layers 31R, 31G, and 31B are configured with different fluorescent materials in order to emit light of different colors according to the subpixels.

A selective wavelength transmitting and reflecting member (band pass filter) that transmits the excitation light L1, and reflects the fluorescence L2 emitted from the phosphor layers 31R, 31G, and 31B may be provided on the outer surface side of the excitation light incident surfaces 31a of the phosphor layers 31R, 31G, and 31B. Here, the expression “transmitting excitation light” means transmitting at least light corresponding to a peak wavelength of excitation light. Also, the expression “reflecting fluorescence emitted from the phosphor layers 31R, 31G, and 31B” means reflecting at least light corresponding to light emission peak wavelengths emitted from the respective phosphor layers 31R, 31G, and 31B.

As illustrated in FIG. 4, the partition wall 35 has a structure of stacking a light absorbing layer 36 that has light absorbing properties and a light scattering layer 37 that has light scattering properties from the substrate 30 side.

As described above, the efficiency of extracting light from the phosphor layer to the outside of the transparent substrate can be enhanced by using, as the partition walls 35, the material that reflects or scatters the fluorescence generated from the phosphor layer and further providing the band pass filter.

The shape of the partition wall 35 is tapered so that the opening portion on the side opposite the substrate 30 is wider than the opening portion on the side of the substrate 30.

The excitation light is effectively incident on the pixel portion by using the partition wall described above, and the reflection of the external light is suppressed so that display with high contrast can be obtained.

Further, the partition wall 35 may be formed of a material reflecting the fluorescence generated in the phosphor layer 31. Accordingly, fluorescence components that leak from side surfaces of the phosphor layers 31 can be reflected. Further, a configuration in which only the surfaces of the partition walls 35 are covered with reflective materials may be employed. Examples of the reflective material include reflective metal such as aluminum, silver, gold, an aluminum-lithium alloy, an aluminum-neodymium alloy, and an aluminum-silicon alloy.

The shapes of the partition walls 35 may be various shapes, such as a lattice shape or a stripe shape, so that the partition walls 35 surround the circumferences of the phosphor layers 31R, 31G, and 31B.

In the display device 100A according to the embodiment, the red color filter 34R is provided between the substrate 30 and the red phosphor layer 31R. The green color filter 34G is provided between the substrate 30 and the green phosphor layer 31G. The blue color filter 34B is provided between the substrate 30 and the blue phosphor layer 31B. Accordingly, chromaticity can be enhanced.

With respect to the thicknesses of the light absorbing layer 36 and the color filters 34, it is desirable that the thicknesses of each of the color filters 34 be more than the thickness of the light absorbing layer 36. If the thicknesses of each of the color filters 34 is smaller than the thickness of the light absorbing layer 36, the side surfaces of the phosphor layers 31 and the light absorbing layer 36 may come into contact with each other. Accordingly, the light emitted from the phosphor layers 31 is absorbed in the light absorbing layer 36, and the light extraction efficiency decreases.

Hereinafter, the components and the manufacturing methods of the phosphor substrate 20 according to the embodiment are described in detail, but the components and the manufacturing methods of the phosphor substrate 20 are not limited thereto.

(Substrate)

Since it is necessary to extract the fluorescence L2 from the phosphor layers 31R, 31G, and 31B to the outside, the substrate 30 to be used as the phosphor substrate 20 used in the embodiment is required to transmit the fluorescence L2 from light emitting areas of the phosphor layers 31R, 31G, and 31B. Therefore, for example, an inorganic material substrate made of glass, quartz, or the like, and a plastic substrate made of polyethylene telephthalate, polycarbazole, polyimide, or the like can be used as the substrate 30 to be used as the phosphor substrate 20. However, the substrate 30 to be used as the phosphor substrate 20 is not limited thereto.

(Phosphor Layer)

The phosphor layers 31R, 31G, and 31B according to the embodiment are formed of the fluorescent material described above, that is, materials obtained by dispersing and mixing fine particles into phosphors, and are configured with the red phosphor layer 31R, the green phosphor layer 31G, the blue phosphor layer 31B that absorb the excitation light L1 from the light sources 2 such as an ultraviolet light emitting organic EL element, a blue light emitting organic EL element, an ultraviolet light emitting LED, or a blue LED, and emit light of red, green, and blue. However, if blue light emission is applied as the light source 22, it is possible to emit the blue excitation light L1 from the blue subpixel PB without providing the blue phosphor layer 31B. Also, if the blue light emission having directivity is used as the light source 22, the light scattering layer capable of scattering the excitation light L1 having the directivity and emitting the excitation light L1 as the isotropic light emission to the outside can be applied without providing the blue phosphor layer 31B.

If necessary, it is preferable to add phosphor layers that emit cyan light and yellow light to the pixels. In a chromaticity coordinate, color purity of the respective pixels that emit cyan light and yellow light is positioned outside of a triangle obtained by connecting points indicating color purity of the pixels that emit red, green, and blue light so that a color reproduction range can be increased compared to the display device using pixels generating three primary colors of red, green, and blue.

The thicknesses of the phosphor layers 31 described above generally range from about 100 nm to 100 μm, but preferably range from 1 μm to 100 μm. If the thickness is less than 100 nm, the excitation light from the light source cannot be sufficiently absorbed. Therefore, the light emission efficiency may decrease, and the color purity may deteriorate because of the mixture of the transmitted light of the excitation light into the required color. Further, it is preferable to set the thickness to be equal to or more than 1 μm in order to enhance the absorption of the excitation light from the light source and decrease the transmitted light of the excitation light to the extent that color purity is not deteriorated. Also, if the thickness exceeds 100 μm, the increase of the thickness does not lead to an increase in efficiency because the excitation light from the light source is already sufficiently absorbed, and merely increases the consumption of materials. Therefore, the increase of the thickness leads to the increase in the cost of the materials.

(Light Scattering Layer)

Meanwhile, if the light scattering layer is applied instead of the blue phosphor layer 31B, light scattering particles can be configured with organic materials, inorganic materials, or a combination thereof. However, it is preferable that light scattering particles be configured with inorganic materials. Accordingly, the light having directivity from the light sources 22 can be more isotropically and effectively dispersed and scattered.

It is possible to provide a light scattering layer which is stable against light or heat by using inorganic materials. It is preferable to use highly transparent particles as the light scattering particles. Also, with respect to the light scattering particles, it is preferable that the fine particles having a refractive index higher than a base material are dispersed in the base material having a low refractive index. In order to effectively scatter the blue light with the light scattering layer, the particle diameters of light scattering particles are required to be in the range of the Mie scattering. Therefore, it is preferable that the particle diameters of the light scattering particles range from about 100 nm to 500 nm.

If inorganic materials are used as the light scattering particles, particles (fine particles) or the like including an oxide of at least one kind of metal selected from the group consisting of silicon, titanium, zirconium, aluminum, indium, zinc, tin, and antimony, as a main component may be used.

For example, silica beads, alumina beads, titanium oxide beads, zirconia oxide beads, zinc oxide beads, and barium titanate (BaTiO₃) can be used.

If particles configured with organic materials (organic fine particles) are used as the light scattering particles, for example, polymethyl methacrylate beads, acrylic beads, acrylic-styrene copolymer beads, melamine beads, high refractive index melamine beads, polycarbonate beads, styrene beads, crosslinked polystyrene beads, polyvinyl chloride beads, benzoguanamine-melamine formaldehyde beads, silicone beads, or the like may be used.

As resin materials to be used by being mixed with the light scattering particles described above, transparent resins are preferable. Also, as resin materials, an acryl resin, a melamine resin, nylon, polystyrene, melamine beads, polycarbonate, polyvinyl chloride, polyvinylidene chloride, polyvinyl acetate, polyethylene, polymethylmethacrylate, poly MBS, medium density polyethylene, high density polyethylene, tetrafluoroethylene, polychloro trifluoroethylene, and polytetrafluoroethylene may be used.

In order to enhance the efficiency of extracting the light penetrating the scattering layer to the outside, the refractive index of the scattering layer may be decreased by adding fine particles which have a refractive index equal to or lower than 1.3 into the scattering layer in the same manner that fine particles are added to the phosphor layer.

In the phosphor layer and the light scattering layer, the low refractive index fine particles may be evenly dispersed, or may be provided to have a concentration gradient.

(Partition Wall)

A Black matrix or metal which is used as partition walls of a display in the related art may be used as materials of the partition walls 35. However, in order to enhance the light extraction efficiency on the emission side, it is desirable to use light scattering partition walls formed with the light scattering material in which light scattering particles having a refractive index higher than that of a resin are dispersed in the resin having a low refractive index. More preferably, in order to achieve both the high contrast and the high light extraction efficiency, after the light absorbing layer having a thickness of about 0.01 μm to 3 μm is formed on the substrate, the light scattering layer having a thickness of about 1 μm to 100 μm that comes into contact with the light absorbing layer in a contact area which is smaller than the contact area of the light absorbing layer with the substrate is formed. However, in order to enhance the light extraction efficiency caused by the light scattering effect, the thickness of the light scattering layer is required to be sufficiently more than that of the light absorbing layer.

As the resin, for example, an acryl resin, a melamine resin, nylon, polystyrene, melamine beads, polycarbonate, polyvinyl chloride, polyvinylidene chloride, polyvinyl acetate, polyethylene, polymethylmethacrylate, poly MBS, medium density polyethylene, high density polyethylene, tetrafluoroethylene, polychloro trifluoroethylene, and polytetrafluoroethylene may be used.

If inorganic materials are used as the light scattering particles, particles (fine particles) or the like including an oxide of at least one kind of metal selected from the group consisting of silicon, titanium, zirconium, aluminum, indium, zinc, tin, and antimony, as a main component may be used. Further, for example, silica beads, alumina beads, titanium oxide beads, zirconia oxide beads, zinc oxide beads, and barium titanate (BaTiO₃) may be used. If particles configured with organic materials (organic fine particles) are used as the light scattering particles, for example, polymethyl methacrylate beads, acrylic beads, acrylic-styrene copolymer beads, melamine beads, high refractive index melamine beads, polycarbonate beads, styrene beads, crosslinked polystyrene beads, polyvinyl chloride beads, benzoguanamine-melamine formaldehyde beads, silicone beads, or the like may be used.

As a method of forming the partition walls 35, a photolithography method, a screening printing method, an evaporation method, a sandblast method, a transfer method, or the like may be used. It is desirable to form the partition walls by the photolithography method because the partition walls having high definition and a high aspect ratio can be formed at low cost. It is possible to cause the partition wall material to be a negative photoresist by selecting an alkali soluble resin as a resin configuring the partition wall material and adding a photopolymerizable monomer, a photopolymerization initiator, and a solvent, or to cause the partition wall material to be a positive photoresist by adding a photosensitive agent such as diazonaphthoquinone instead of the photopolymerizable monomer or the photopolymerization initiator, and the patterning can be performed by the photolithography method.

Further, it is preferable that horizontal and vertical sizes of the opening portion (one section in phosphor layer) of the partition wall 35 range from about 20 μm×20 μm to about 500 μm×500 μm.

(Color Filter)

In the phosphor substrate 20 according to the embodiment, the color filters are provided between the phosphor layers 31R, 31G, and 31B and the substrate 30 on the light extraction side. As the color filters, the known color filters can be used. Here, the color purity of the red subpixel PR, the green subpixel PG, and the blue subpixel PB can be enhanced by providing the color filters. Therefore, the color reproduction range of the display device 100A can be increased.

The red color filter 34R that faces the red phosphor layer 31R absorbs the excitation light of the external light that excites the red phosphor layer 31R. Therefore, it is possible to decrease or prevent the light emission of the red phosphor layer 31R caused by the external light, and it is possible to decrease or prevent the deterioration of the contrast. In addition, it is possible to prevent the leakage of the excitation light L1 that is not absorbed in the red phosphor layer 31R and penetrates the red phosphor layer 31R, to the outside by using the red color filter 34R. Therefore, it is possible to prevent the decrease of the color purity of the emitted light caused by the mixing of the colors of the excitation light L1 and the emitted light from the red phosphor layer 31R.

In the same manner, the green color filter 34G that faces the green phosphor layer 31G absorbs the excitation light of the external light that excites the green phosphor layer 31G. Therefore, it is possible to decrease or prevent the light emission of the green phosphor layer 31G caused by the external light, and it is possible to decrease or prevent the deterioration of the contrast. In addition, it is possible to prevent the leakage of the excitation light L1 that is not absorbed in the green phosphor layer 31G and penetrates the green phosphor layer 31G, to the outside by using the green color filter 34G. Therefore, it is possible to prevent the decrease in the color purity of the emitted light caused by mixed colors of the excitation light L1 and the emitted light from the green phosphor layer 31G.

In the same manner, the blue color filter 34B that faces the blue phosphor layer 31B absorbs the excitation light of the external light that excites the blue phosphor layer 31B. Therefore, it is possible to decrease or prevent the light emission of the blue phosphor layer 31B caused by the external light, and it is possible to decrease or prevent the deterioration of the contrast. In addition, it is possible to prevent the leakage of the excitation light L1 that is not absorbed in the blue phosphor layer 31B and penetrates the blue phosphor layer 31B, to the outside by using the blue color filter 34B. Therefore, it is possible to prevent the decrease in the color purity of the emitted light caused by mixed colors of the excitation light L1 and the emitted light from the blue phosphor layer 3B.

[Phosphor Substrate]

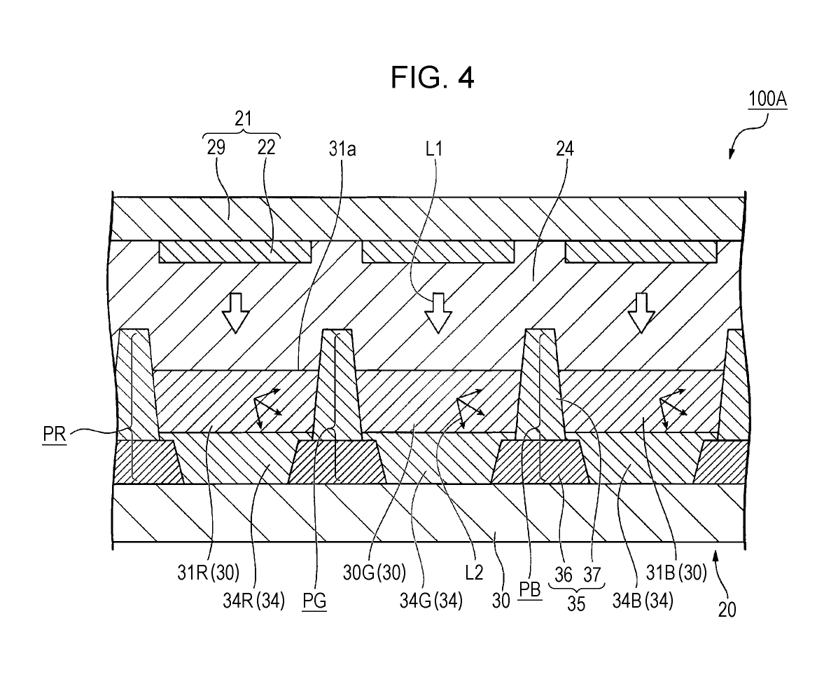

Hereinafter, the phosphor substrate 20 according to the embodiment is described with reference to FIG. 5.

FIG. 5 is a cross-sectional view illustrating the phosphor substrate 20A according to the first embodiment.

The basic configuration of the phosphor substrate 20A according to the embodiment is the same as that of the phosphor substrate of the display device according to the first embodiment, and shapes of phosphor layers 31RA, 31GA, and 31BA provided in areas surrounded by the partition walls 35 are different from the shape of the phosphor substrate of the display device according to the first embodiment.

In FIG. 5, components used in common in FIG. 4 are denoted by the same reference numerals, and detailed descriptions thereof are omitted.

As illustrated in FIG. 5, in the phosphor substrate 20A according to the embodiment, shapes of vertical cross sections of the phosphor layers 31RA, 31GA, and 31BA of the areas surrounded by the partition walls 35 have a concave shape. The peripheral portions of the phosphor layers 31RA, 31GA, and 31BA are arranged along with the side surfaces of the partition walls 35. With respect to the phosphor layers 31RA, 31GA, and 31BA, the upper surfaces of the center portions of the phosphor layers 31RA, 31GA, and 31BA are flat. The heights of the upper surfaces of the center portions of the phosphor layers 31RA, 31GA, and 31BA are substantially half the height of the partition walls 35. Meanwhile, the heights of the peripheral portions of the phosphor layers 31RA, 31GA, and 31BA are substantially the same as the heights of the partition walls 35.

According to the configuration of the embodiment, it is possible to suppress the excitation light from the light source to the pixel from being absorbed in the partition walls 35 or penetrating the partition walls 35. Accordingly, it is possible to improve the light extraction efficiency.

[Display Device: Second Embodiment]

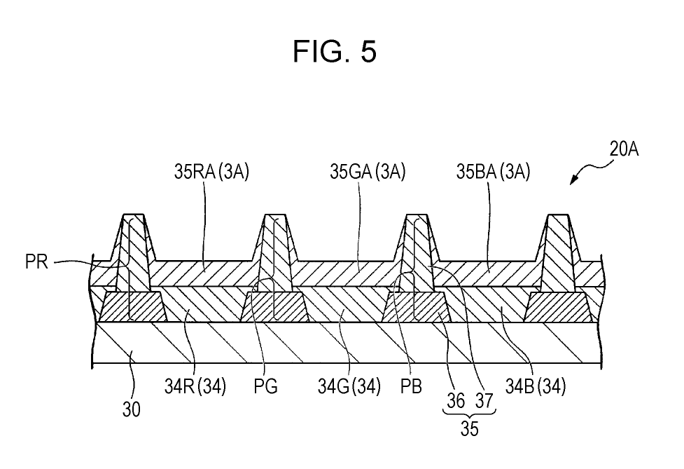

Hereinafter, a display device 100B according to a second embodiment of the invention is described with reference to FIG. 6.

FIG. 6 is a cross-sectional view illustrating the display device 100B according to the second embodiment.

The basic configuration of the display device 100B according to the embodiment is the same as that of the display device according to the first embodiment, and the configurations of partition walls 35B are different from those of the display device according to the first embodiment. Therefore, in the embodiment, the description of the basic configuration of the display device 100B is omitted, and the partition walls 35B are described.

In the display device 100B according to the embodiment, a black layer 38 is provided on the upper surface of the light scattering layer 37. Accordingly, since a portion of the excitation light emitted from the light sources 22 is absorbed in the black layer 38, it is possible to avoid the color mixture by suppressing the leakage of the light to adjacent pixels. The thickness of the black layer 38 is less than that of the light scattering layer 37. For example, the thickness of the black layer 38 is about 0.01 μm to 3 μm. Also, the width of the black layer 38 is the same as that of the upper surface of the light scattering layer 37.

In the embodiment, the black layer 38 is provided on the upper surface of the light scattering layer 37, and the light absorbing layer 36 is provided on the lower surface of the light scattering layer 37. However, the embodiment is not limited thereto. For example, only the black layer 38 may be provided on the upper surface of the light scattering layer 37, and the light absorbing layer 36 may not be provided on the lower surface of the light scattering layer 37.

[Display Device: Third Embodiment]

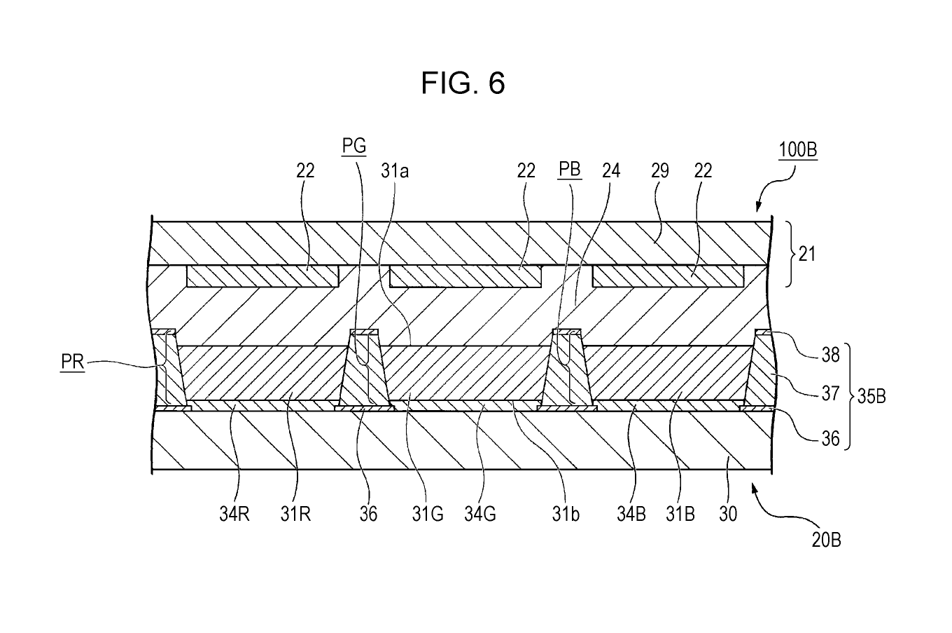

A display device 100C according to a third embodiment of the invention is described with reference to FIG. 7.

FIG. 7 is a cross-sectional view of the display device 100C according to the third embodiment.

The basic configuration of the display device 100C according to the embodiment is the same as that of the display device according to the second embodiment, and different from that of the display device according to the fourth embodiment in that planarized layers 33 are provided on the upper surfaces of the phosphor layers 31R, 31G, and 31B and a band pass filter 32 is provided on the upper surfaces of the planarized layers 33. Accordingly, the description of the basic configuration of the display device 100C is omitted in the embodiment.

In the display device 100C according to the embodiment, the planarized layers 33 are formed on the upper surfaces of the respective phosphor layers 31R, 31G, and 31B of a phosphor substrate 20C. The band pass filter 32 is provided on the upper surfaces of the planarized layers 33 and the partition walls 35C.

When the blue light is emitted from the light sources 22 as the excitation light, the band pass filter 32 has a function of transmitting light in the blue area (light in the range of 435 nm to 480 nm in wavelength) and reflecting light in the green area to the infrared area (light outside the range of the blue area in wavelength). The band pass filter 32 is configured with a thin film made of gold, silver, or the like, or a dielectric multilayer film.

Blue light emitted from the light sources 2 penetrates the band pass filter 32, the wavelength of the blue light is converted by the phosphor layers 31, and green light or red light can be emitted. Further, since the band pass filter 32 reflects the green light or the red light toward the band pass filter 32 back to the phosphor layer side, the green light or the red light can be effectively used, and the improvement of the light extraction efficiency can be expected.

In the embodiment, although the band pass filter 32 is provided on the upper surface of the planarized layers 33, the embodiment is not limited thereto. For example, the planarized layers 33 may not be provided, and the band pass filter 32 may be provided on the upper surfaces of the respective phosphor layers 31R, 31G, and 31B formed on the opening portions of the partition walls 3. That is, the band pass filter 32 may be provided between the light source substrate 21 and the phosphor substrate 20C.

If ultraviolet light is emitted from the light sources 22 as the excitation light, the band pass filter 32 may have a function of transmitting light in the ultraviolet area (light in the range of equal to or more than 360 nm and equal to or less than 435 nm in wavelength), and reflecting light in the green area to the infrared area (light outside the range of the ultraviolet area in wavelength). Accordingly, the ultraviolet light emitted from the light sources 22 penetrates the band pass filter 32, the wavelength of the ultraviolet light is converted by the phosphor layers 31, and the green light or the red light can be emitted. Further, since the band pass filter 32 reflects green light or red light toward the band pass filter 32 back to the phosphor layer side, the green light or the red light can be effectively used.

(Light Source)

Subsequently, the light sources 22 according to the embodiment are described.

As the light sources 22 that excite the phosphor layers 31R, 31G, and 31B, it is preferable to use ultraviolet light and blue light. As the light sources 22, for example, an ultraviolet LED, a blue LED, an ultraviolet light emitting inorganic EL, a blue light emitting inorganic EL, an ultraviolet light emitting organic EL, and a blue light emitting organic EL may be used, but the embodiment is not limited thereto. Also, the ON/OFF states of the light emission for displaying the image can be controlled by directly switching the light sources 22. Also, the ON/OFF states of the light emission can be controlled by providing a layer having a shutter function such as a liquid crystal layer between the phosphor layers 31R, 31G, and 31B and the light sources 22 and controlling the layer.

In addition, it is possible to control the ON/OFF states the layer having the shutter function such as the liquid crystal layer and the light sources 22.

As the light sources 22, an ultraviolet LED, a blue LED, an ultraviolet light emitting inorganic EL, a blue light emitting inorganic EL, an ultraviolet light emitting organic EL, and a blue light emitting organic EL, which are known can be used. The material and a manufacturing method of the light sources 22 are not particularly limited, and a known material, and a known manufacturing method can be used. It is preferable that the main light emission peak of the ultraviolet light be equal to or more than 360 nm and less than 435 nm, and the main light emission peak of the blue light be equal to or more than 435 nm and equal to or smaller than 480 nm. It is desirable that the light sources 22 have directivity. The directivity refers to the characteristic in which the intensity of the light is different according to the directions thereof. The directivity may be provided when the light is incident on the phosphor layer. It is desirable that the light sources 22 cause parallel light to be incident on the phosphor layer.

The degree of the directivity of the light sources 22 may be equal to or less than ±30° of the half-value width, and preferably be equal to or less than ±10°. This is because if the degree is more than 30° of the half-value width, the light emitted from the backlight is incident on unintended pixels and excites unintended phosphors so that color purity or contrast decreases.

Hereinafter, light source 22A is described as an example that can be suitably used as the light source 22.

(LED)

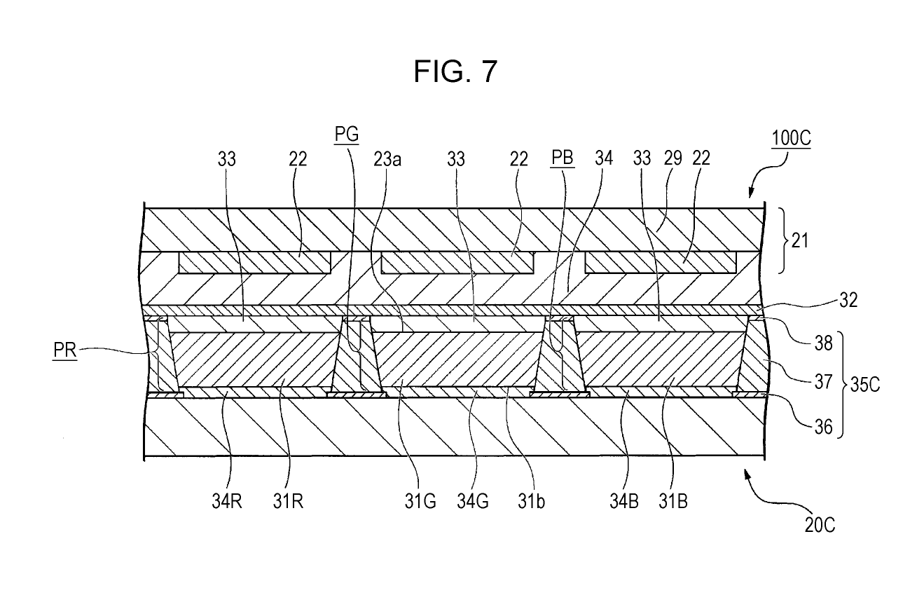

As illustrated in FIG. 8, a light emitting diode (LED) can be used as the light source 22A. As the LED, a known LED can be used, and for example, an ultraviolet light emitting inorganic LED and a blue light emitting inorganic LED are suitably used. The LED may be the light source 22A in which a first buffer layer 43, an n-type contact layer 44, a second n-type clad layer 45, a first n-type clad layer 46, an active layer 47, a first p-type clad layer 48, a second p-type clad layer 49, and a second buffer layer 40 are sequentially stacked on one surface of a substrate 39, a cathode 42 is formed on the n-type contact layer 44, and an anode 41 is formed on the second buffer layer 40. However, the specific configuration of the LED is not limited thereto.

(Organic EL Element)

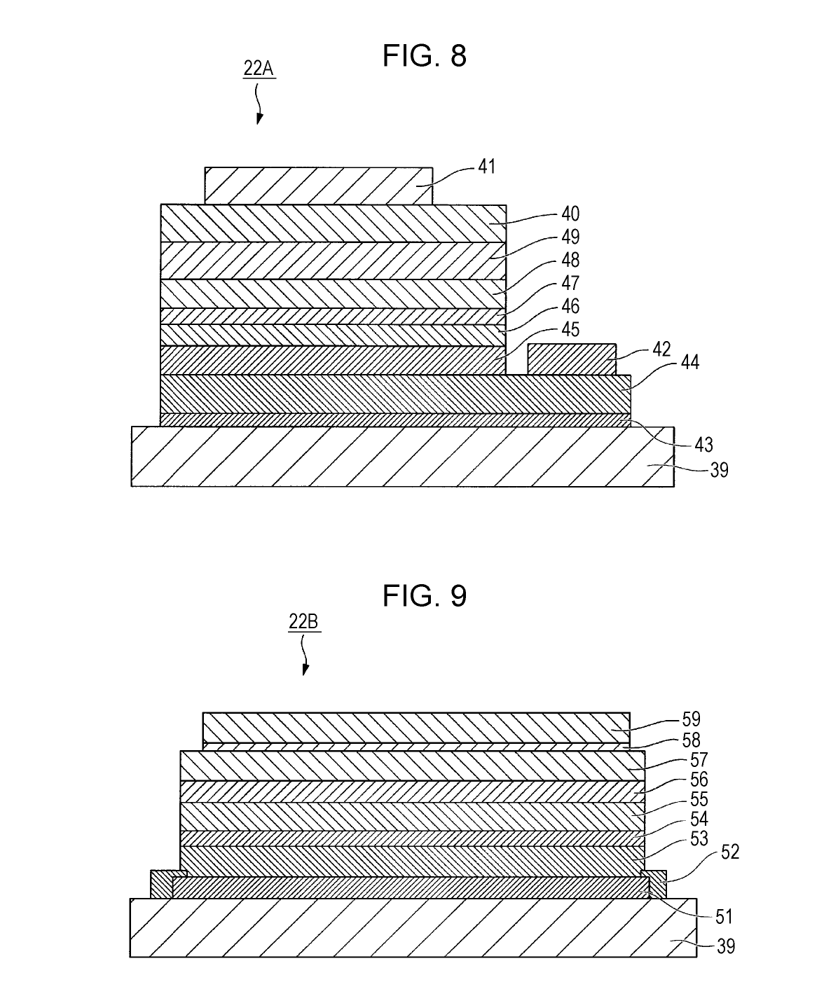

As illustrated in FIG. 9, the organic EL element can be used as a light source 22B. As the organic EL element according to the embodiment, the known organic EL can be used. The organic EL element 22B is the light source 22B, for example, in which the anode 51, a hole injection layer 53, a hole transport layer 54, a luminous layer 55, a hole preventing layer 56, an electron transport layer 57, an electron injection layer 58, and a cathode 59 are sequentially stacked on one surface of the substrate 39. An edge cover 52 is formed so as to cover an end surface of the anode 51.

As an organic EL element 23B, an organic EL layer including the luminous layer (organic luminous layer) 55 formed of at least an organic light emitting material may be provided between the anode 51 and the cathode 59, and the specific configuration is not limited thereto. In the description below, layers from the hole injection layer 53 to the electron injection layer 58 may be referred to as an organic EL layer.

The organic EL elements 22B are provided in a matrix shape respectively corresponding to each of the red subpixel PR, the green subpixel PG, and the blue subpixel PB illustrated in FIG. 4, and ON/OFF states of the subpixels can be separately controlled.

A method of driving the plurality of organic EL elements 2B may be active matrix driving or passive matrix driving.

(Inorganic EL Element)

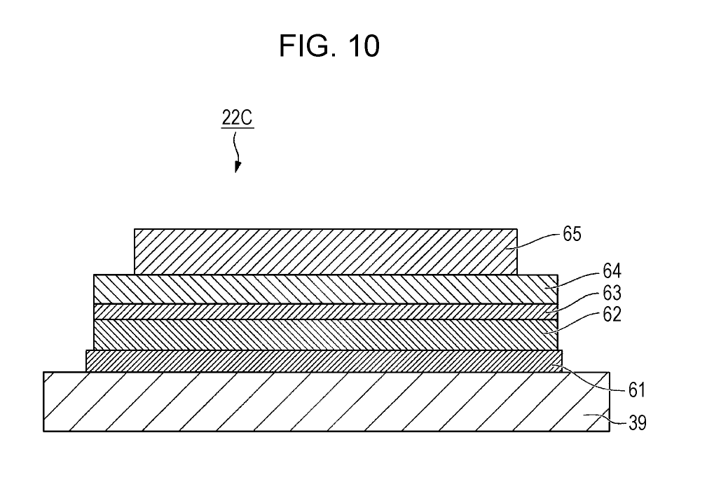

As illustrated in FIG. 10, the inorganic EL element can be used as a light source 22C. As the inorganic EL element, a known inorganic EL element can be used, and for example, the ultraviolet light emitting inorganic EL element and the blue light emitting inorganic EL element are suitably used. The inorganic EL element is the light source 22C, for example, in which a first electrode 61, a first dielectric layer 62, a luminous layer 63, a second dielectric layer 64, and a second electrode 65 are sequentially stacked on one surface of the substrate 39. In addition, the specific configuration of the inorganic EL element is not limited thereto.

[Display Device: Fourth Embodiment]

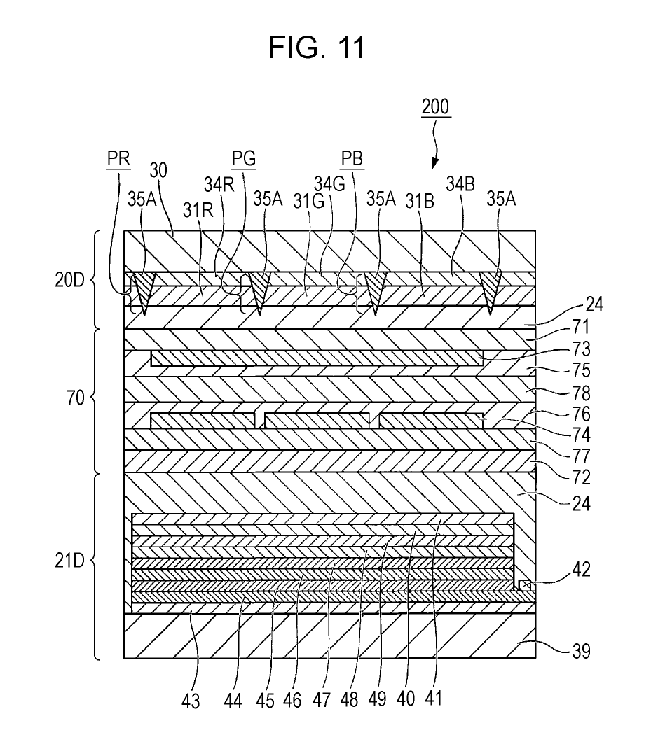

FIG. 11 is a cross-sectional view schematically illustrating a display device 200 according to a fourth embodiment. The display device 200 is a configuration example in which a liquid crystal device 70 which is an optical member is inserted between a phosphor substrate 20D and a light source substrate 21D formed of the LED light source. In FIG. 11, components used in common in the display device 100 according to the first embodiment illustrated in FIG. 4 are denoted by the same reference numerals, and the detailed descriptions thereof are omitted.

The stacked structure of the LED light source substrate 21D is the same as that illustrated in FIG. 8, the common components are denoted by the same reference numerals, and the detailed description is omitted. Also, the liquid crystal device 70 has a configuration in which voltages to be applied to a liquid crystal layer 78 by using a pair of electrodes 73 and 74 can be controlled for each pixel, and controls transmittance of light emitted from the entire surface of the light sources for each pixel. That is, the liquid crystal device 70 has a function as an optical shutter that selectively transmits light from the LED light source substrate 21D for each pixel.

As the liquid crystal device 70 according to the embodiment, a known liquid crystal device can be used, and for example, a pair of polarizing plates 71 and 72, the electrodes 73 and 74, oriented films 75 and 76, and a substrate 77 are included, and the liquid crystal layer 78 is interposed between the oriented films 75 and 76. Further, one optically anisotropic layer may be disposed between a liquid crystal cell and one of the polarizing plates 71 and 72, or two optically anisotropic layers may be provided between the liquid crystal cell and both of the polarizing plates 71 and 72.

The liquid crystal cell is not particularly limited, and can be appropriately selected according to purpose. For example, a TN mode, a VA mode, an OCB mode, an IPS mode, and an ECB mode can be included. The liquid crystal device 70 may be driven by passive driving, or by active driving using a switching element such as a TFT.

The phosphor substrate 20D, the liquid crystal device 70, and the LED light source element substrate 21D are bonded with the bonding layers 24 and are integrated. That is, the polarizing plate 71 of the liquid crystal device 70 and the surface of the phosphor substrate 20D on which the phosphor layers 31R, 31G, and 31B are formed are bonded with the bonding layer 24. Also, the polarizing plate 72 of the liquid crystal device 70 and the surface of the LED light source element substrate 21D on which the LED is formed are bonded with the bonding layers 24.

As the polarizing plates 71 and 72, it is preferable that the extinction ratio of at least one of the polarizing plates 71 and 72 in the wavelength of equal to or more than 435 nm and equal to or less than 480 nm be equal to or more than 10,000. The extinction ratio can be measured by a method of a rotating analyzer using a Glan-Thompson prism. The extinction ratios are indicated as unique characteristics of the polarizing plate 71 and the polarizing plate 72, and are defined as follows.

Extinction ratio=(Polarizing transmittance in the direction of transmission axis of polarizing plate)/(Polarizing transmittance in the direction of absorption axis of polarizing plate)

The polarizing transmittance refers to the transmittance obtained when ideal polarization light is incident by using the Glan-Thompson prism.

The liquid crystal in the related art is generally designed so that the contrast and the transmittance are optimum mainly in an area of 550 nm, and the extinction ratio of the iodine polarizing plate which is used as the liquid crystal in the related art in the short wavelength area equal to or lower than 490 nm is about 2,000 to 3,000 (extinction ratios in green area and red area are about 10,000). In contrast, the blue excitation-type displaying polarizing plate using blue light backlight according to the embodiment can be designed to be optimum in the blue area. Therefore, the polarizing plate having the extinction ratio of equal to or more than 10,000 in the blue area is used.

In this manner, the contrast of the panel can be increased by using the polarizing plate having the high extinction ratio. Further, since the transmittance is high in the polarizing plate with a high extinction ratio, the usage efficiency of the light of the backlight is enhanced. Therefore, power consumption can be reduced.

[Display Device: Fifth Embodiment]

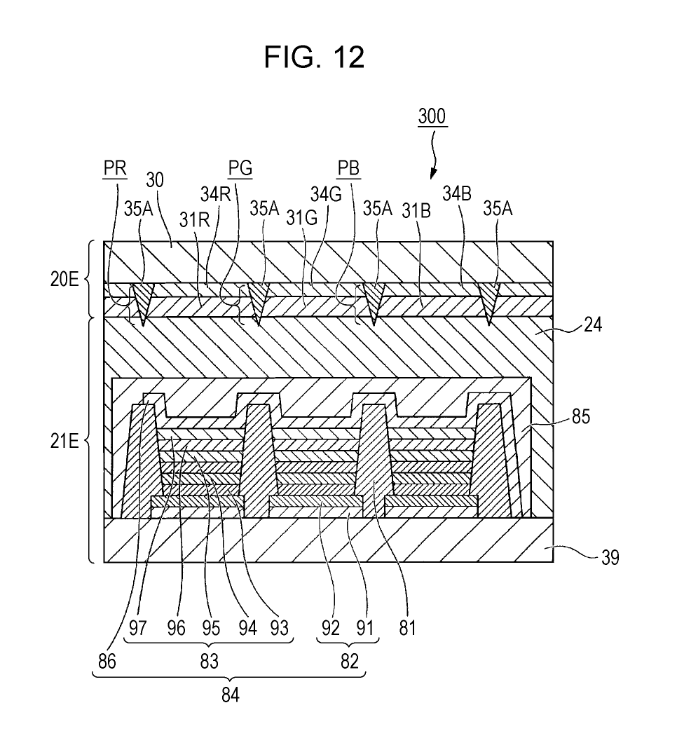

FIG. 12 is a cross-sectional view schematically illustrating a display device 300 according to a fifth embodiment. The display device 300 is a configuration example in which a phosphor substrate 20E and an organic EL element light source substrate 21E formed of the organic EL element light source are stacked. In FIG. 12, the components used in common in the display device 100A according to the first embodiment are denoted by the same reference numerals, and the detailed descriptions thereof are omitted.

The organic EL element light source substrate 21E is provided on one surface of the substrate 39, and is configured with an organic electroluminescence portion (hereinafter, referred to as “organic EL portion”) 84 in which an organic layer 83 is interposed between a first electrode 81 and a second electrode 82 and a sealing film 85 that seals the organic EL portion 84.

The first electrode 82 is installed on one surface of the substrate 39, and is configured with reflecting electrodes 91 and transparent electrodes 92 provided on the reflecting electrodes 91.

The organic layer 83 is configured with a hole injection layer 93, a hole transport layer 94, an organic luminous layer 95, an electron transport layer 96, and an electron injection layer 97 which are sequentially stacked from the first electrode 82 side to the second electrode 86 side.

The phosphor substrate 20E and the organic EL element light source substrate 21E are bonded with the bonding layer 24 and are integrated. That is, the surface of the phosphor substrate 20E on which the phosphor layers 31R, 31G, and 31B are formed and the light emitting surface of the organic EL element light source substrate 21E are bonded with the bonding layer 24.

[Electronic Apparatus]

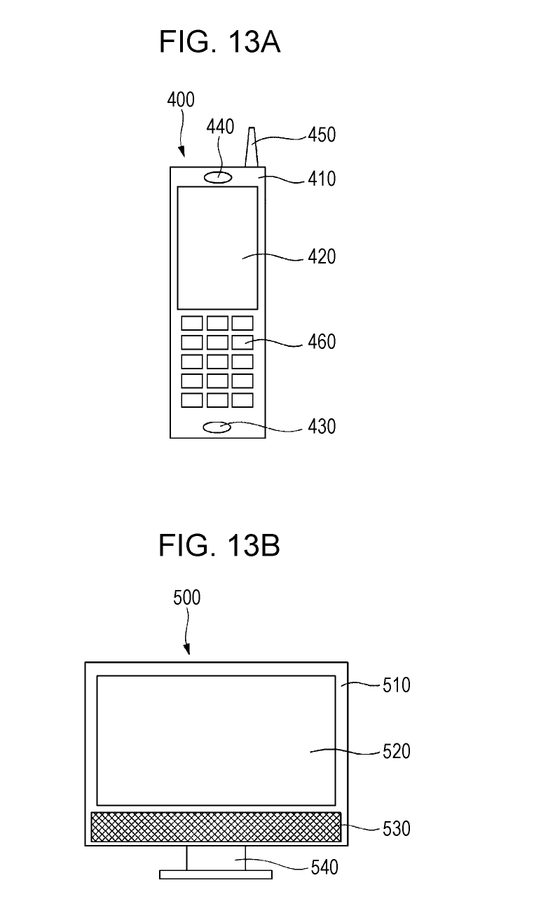

As an example of the electronic apparatus including the display device according to the embodiments described above, a mobile phone illustrated in FIG. 13A, and a television receiving apparatus illustrated in FIG. 13B are included.

A mobile phone 400 illustrated in FIG. 13A includes a main body 410, a display portion 420, a voice input portion 430, a voice output portion 440, an antenna 450, operation switches 460, and the like, and the display device according to the embodiments described above is provided in the display portion 420.

A television receiving apparatus 500 illustrated in FIG. 13B includes a main body cabinet 510, a display portion 520, a speaker 530, a stand 540, and the like, and the display device according to the embodiments described above are used in the display portion 520.

Since the display device according to the embodiments described above is used in the electronic apparatus, an electronic apparatus having good display quality can be realized.

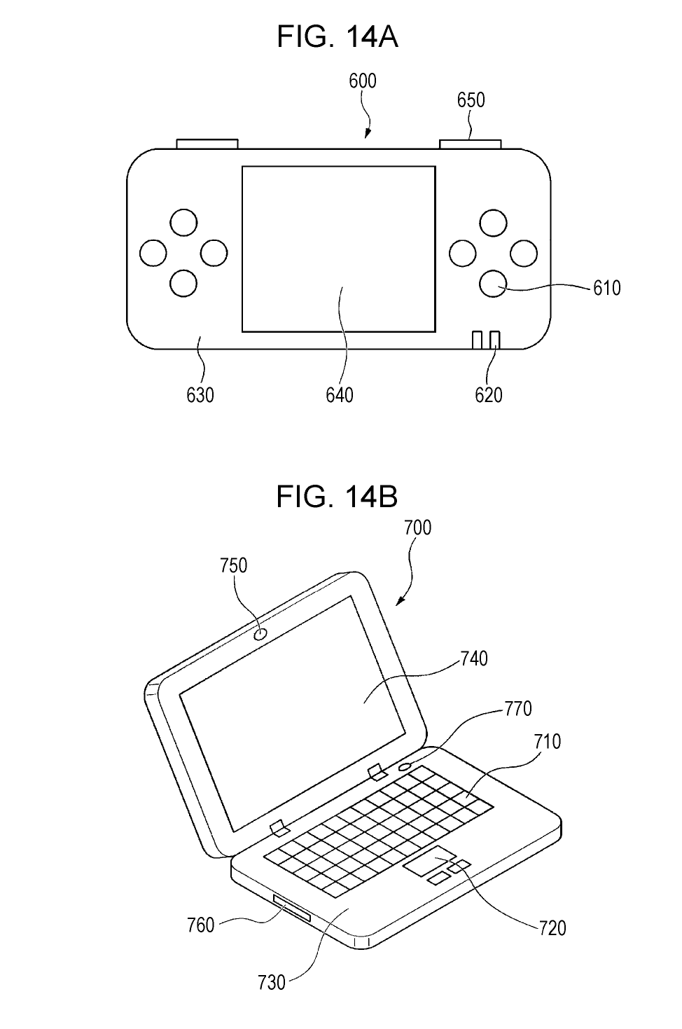

The display device according to an embodiment of the invention can be applied, for example, to a portable game console illustrated in FIG. 14A. A portable game console 600 illustrated in FIG. 14A includes operation buttons 610, LED lamps 620, a housing 630, a display portion 640, infrared ports 650, and the like.

As the display portion 640, the display device according to an embodiment of the invention can be suitably applied. A video with high contrast can be displayed with low power consumption by applying the display device according to an embodiment of the invention to the display portion 640 of the portable game console 600.

The display device according to an embodiment of the invention can be applied, for example, to a notebook computer illustrated in FIG. 14B. A notebook computer 700 illustrated in FIG. 14B includes a keyboard 710, a pointing device 720, a housing 730, a display portion 740, a camera 750, an external connection port 760, a power switch 770, and the like. Also, as the display portion 740 of the notebook computer 700, the display device according to an embodiment of the invention can be suitably applied. The notebook computer 700 that can display a video with high contrast can be realized by applying the display device according to an embodiment of the invention to the display portion 740 of the notebook computer 700.

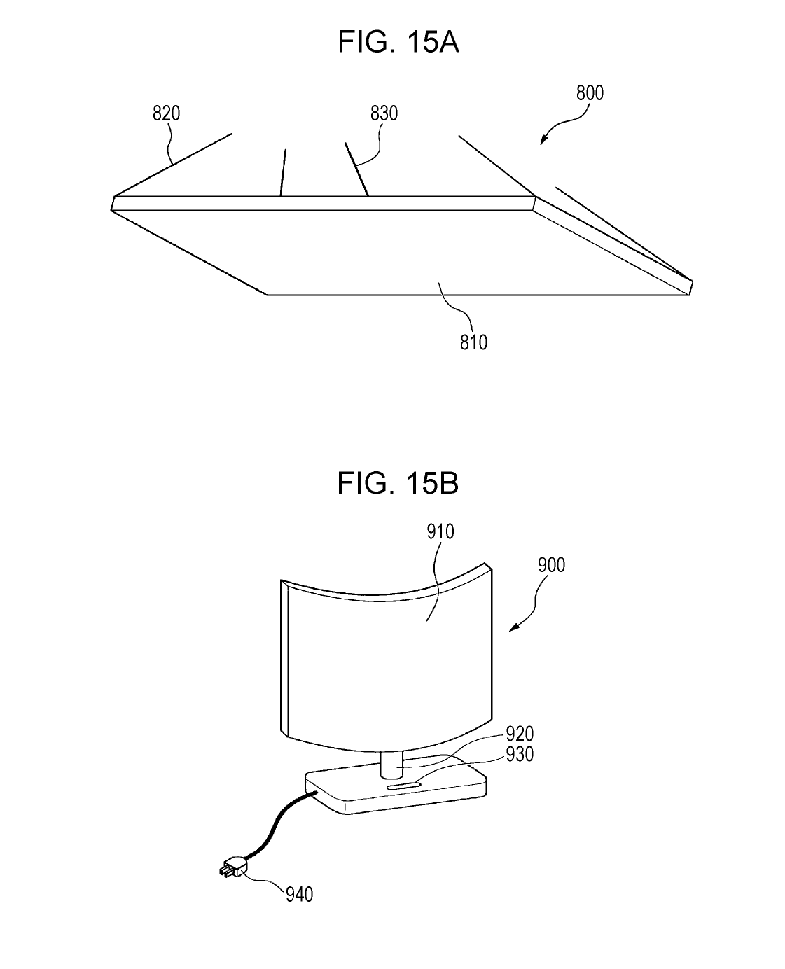

The display device according to an embodiment of the invention can be applied, for example, to a ceiling light illustrated in FIG. 15A. A ceiling light 800 illustrated in FIG. 15A includes an illumination portion 810, a hanging tool 820, a power code 830, and the like. Also, as the illumination portion 810, the display device according to an embodiment of the invention can be suitably applied. It is possible to obtain illumination light with free color tones and to realize a lighting apparatus having high light performance properties by applying the display device according to an embodiment of the invention to the illumination portion 810 of the ceiling light 800. In addition, it is possible to realize the lighting apparatus that can perform surface light emission with even illuminance and high color purity.

The display device according to an embodiment of the invention can be applied, for example, to an illumination stand illustrated in FIG. 15B. An illumination stand 900 illustrated in FIG. 15B includes an illumination portion 910, a stand 920, a power switch 930, and a power code 940, and the like. As the illumination portion 910, the display device according to an embodiment of the invention can be suitably used. It is possible to obtain illumination light with free color tones and to realize a lighting apparatus having high light performance properties by applying the display device according to an embodiment of the invention to the illumination portion 910 of the illumination stand 900. In addition, it is possible to realize a lighting apparatus that can perform surface light emission with even illuminance and high color purity.

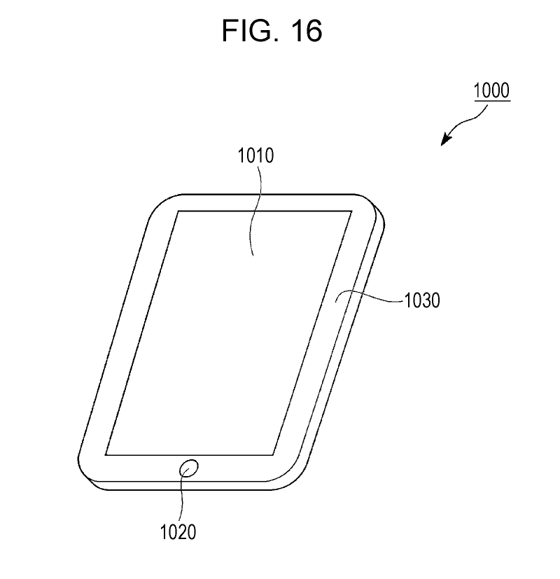

The display device according to an embodiment of the invention can be applied, for example, to a tablet terminal illustrated in FIG. 16. A tablet terminal 1000 illustrated in FIG. 16 includes a display portion (touch panel) 1010, a camera 1020, a housing 1030, and the like.

As the display portion 1010, the display device according to an embodiment of the invention can be suitably applied. A video with a wide viewing angle can be displayed with low power consumption by applying the display device according to an embodiment of the invention to the display portion 1010 of the tablet terminal 1000.

[LED Package]

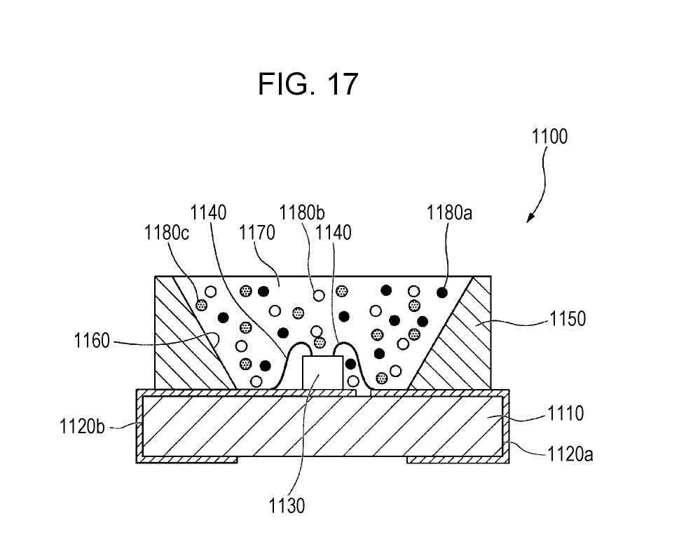

The phosphor substrate according to an embodiment of the invention can be applied, for example, to the LED package illustrated in FIG. 17. In an LED package 1100 illustrated in FIG. 17, and electrode patterns 1120a and 1120b are respectively formed on a substrate 1110, and LED chips 1130 are mounted thereon and electrically connected to the electrode patterns 1120a and 1120b with the wires 1140, and the like. A reflecting frame 1150 is mounted so that the LED chips 1130 are installed in the substrate 1110, and a reflecting layer 1160 is formed inside the reflecting frame 1150.

On the reflecting layer 1160, a reflecting surface is formed by evaporating or painting aluminum (Al) and/or silver (Ag) and the like having a high refractive index. Also, a phosphor layer 1170 is formed in a portion in which the LED chips 1130 are mounted inside the reflecting frame 1150, and includes phosphors 1180a, low refractive index fine particles 1180b and dispersing agents 1180c, and the like in the transparent resin to seal the LED chip 1130. An LED package with high luminance can be realized with low power consumption by applying the phosphor according to an embodiment of the invention to the LED package 1100.

### EXAMPLES

Aspects of the invention are more specifically described by examples and comparative examples, but the aspects of the invention are not limited to the examples.

### Comparative Example 1

As the substrate, glass having the thickness of 0.7 mm was used. After being rinsed, the glass was subjected to 10 minutes of pure water ultrasonic washing, 10 minutes of acetone ultrasonic washing, and 5 minutes of isopropyl alcohol steam washing, and dried for 1 hour at 100° C.

In the process of forming a green phosphor layer, 100 g of the toluene solution in which 10 wt % of PMMA was dissolved was added to 0.1 g of coumarin 545T, and the resultant was heated and stirred to prepare coating liquid for forming green phosphors.

Subsequently, the prepared coating liquid for forming green phosphors was applied to the substrate by using a spinner. Subsequently, the resultant was heated and dried in a vacuum oven (in the condition of 100° C. and 10 mmHg) for 4 hours, so that a green phosphor layer having a refractive index of 1.50 was formed to obtain the phosphor substrate.

The excitation light of the wavelength of 460 nm was applied from the fluorescent layer side of the phosphor substrate, and the light extraction efficiency on the front surface of the phosphor substrate was measured by using a total luminous flux measurement system (HalfMoon manufactured by Otsuka Electronics Co., Ltd.). As the result thereof, the light extraction efficiency was 12.0%.

### Example 1-1

As the substrate, glass having a thickness of 0.7 mm was used. After being rinsed, the glass was subjected to 10 minutes of pure water ultrasonic washing, 10 minutes of acetone ultrasonic washing, and 5 minutes of isopropyl alcohol steam washing, and dried for 1 hour at 100° C.

In the process of forming a green phosphor layer, 100 g of the toluene solution in which 10 wt % of PMMA was dissolved was added to 0.1 g of coumarin 545T, the resultant was heated and stirred, and 40 g of hollow silica fine particles having a refractive index of 1.21 and the particle diameter of 20 nm were added, to prepare coating liquid for forming green phosphors.

Subsequently, the prepared coating liquid for forming green phosphors was applied to the substrate by using a spinner. Subsequently, the resultant was heated and dried in the vacuum oven (in the condition of 100° C. and 10 mmHg) for 4 hours, so that a green phosphor layer having a refractive index of 1.26 was formed to obtain the phosphor substrate.

The excitation light with a wavelength of 460 nm was applied from the fluorescent layer side of the phosphor substrate, and the light extraction efficiency on the front surface of the phosphor substrate was measured by using a total luminous flux measurement system (HalfMoon manufactured by Otsuka Electronics Co., Ltd.). As the result thereof, the light extraction efficiency was 20.1%. The light extraction efficiency was improved by 1.7 times of the efficiency in Comparative example 1.

### Example 1-2

As the substrate, glass having a thickness of 0.7 mm was used. After being rinsed, the glass was subjected to 10 minutes of pure water ultrasonic washing, 10 minutes of acetone ultrasonic washing, and 5 minutes of isopropyl alcohol steam washing, and dried for 1 hour at 100° C.

In the process of forming a green phosphor layer, 100 g of the toluene solution in which 10 wt % of PMMA was dissolved was added to 0.1 g of Lumogen yellow F083, the resultant was heated and stirred, and 40 g of hollow silica fine particles having a refractive index of 1.21 and the particle diameter of 20 nm were added, to prepare coating liquid for forming green phosphors.

Subsequently, the prepared coating liquid for forming green phosphors was applied to the substrate by using a spinner. Subsequently, the resultant was heated and dried in the vacuum oven (in the condition of 100° C. and 10 mmHg) for 4 hours, so that a green phosphor layer was formed to obtain the phosphor substrate.

Finally, the excitation light of the wavelength of 460 nm was applied from the fluorescent layer side of the phosphor substrate, and the light extraction efficiency on the front surface of the phosphor substrate was measured by using a total luminous flux measurement system (HalfMoon manufactured by Otsuka Electronics Co., Ltd.). As the result thereof, the light extraction efficiency was 21.5%. The light extraction efficiency was improved by 1.8 times of the efficiency in Comparative example 1.

### Comparative Example 2

The phosphor substrate was manufactured in the same manner as in the method described in Comparative example 1.

A band pass filter in which transmittance of the light having the wavelength of 460 nm was 85%, and transmittance of the visible light having the wavelength of equal to or more than 480 nm was equal to or less than 5% was bonded to the phosphor substrate by using thermosetting transparent elastomer.

The excitation light of the wavelength of 460 nm was applied from the fluorescent layer side of the phosphor substrate, and the light extraction efficiency on the front surface of the phosphor substrate was measured by using a total luminous flux measurement system (HalfMoon manufactured by Otsuka Electronics Co., Ltd.). As the result thereof, the light extraction efficiency was 22.8%.

### Example 2-1

The phosphor substrate was manufactured in the same manner as in the method described in Example 1-1.

A band pass filter in which transmittance of the light having the wavelength of 460 nm was 85%, and transmittance of the visible light having the wavelength of equal to or more than 480 nm was equal to or less than 5% was bonded to the phosphor substrate by using thermosetting transparent elastomer.

The excitation light with a wavelength of 460 nm was applied from the fluorescent layer side of the phosphor substrate, and the light extraction efficiency on the front surface of the phosphor substrate was measured by using a total luminous flux measurement system (HalfMoon manufactured by Otsuka Electronics Co., Ltd.). As the result thereof, the light extraction efficiency was 45.3%.

### Example 2-2

The phosphor substrate was manufactured in the same manner as in the method described in Example 1-2.

A band pass filter in which transmittance of the light having the wavelength of 460 nm was 85%, and transmittance of the visible light having the wavelength of equal to or more than 480 nm was equal to or less than 5% was bonded to the phosphor substrate by using thermosetting transparent elastomer.

Finally, the excitation light with a wavelength of 460 nm was applied from the fluorescent layer side of the phosphor substrate, and the light extraction efficiency on the front surface of the phosphor substrate was measured by using a total luminous flux measurement system (HalfMoon manufactured by Otsuka Electronics Co., Ltd.). As the result thereof, the light extraction efficiency was 45.9%.

### Comparative Example 3

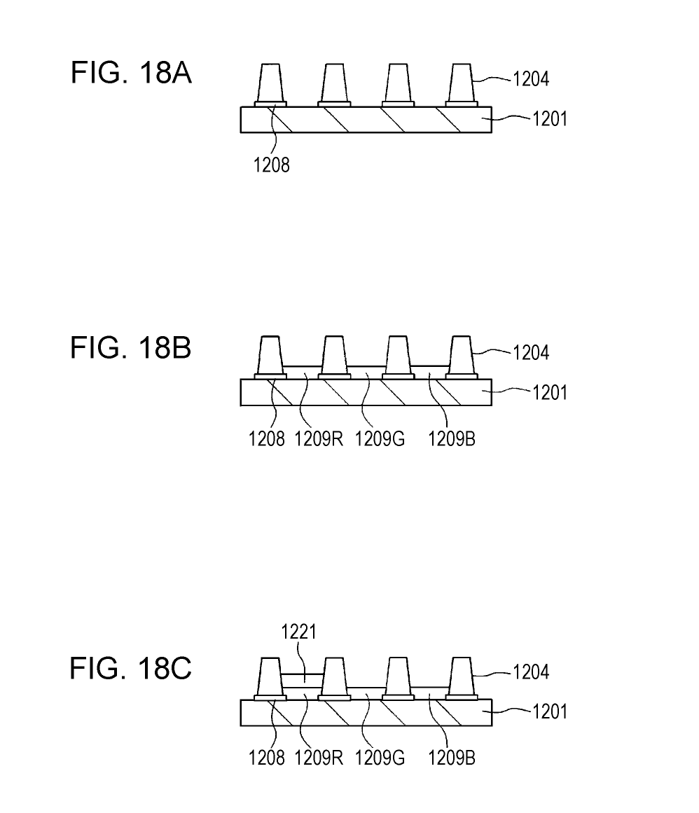

As illustrated in FIG. 18A, the glass having a thickness of 0.7 mm was used as a substrate 1201. After being rinsed, the glass was subjected to 10 minutes of pure water ultrasonic washing, 10 minutes of acetone ultrasonic washing, and 5 minutes of isopropyl alcohol steam washing, and dried for 1 hour at 100° C.

As a black partition wall material, BK resist manufactured by Tokyo Ohka Kogyo Co., Ltd. was coated by using a spin coater. Thereafter, the resultant was prebaked at 70° C. for 15 minutes to form a coating film having a thickness of 1 μm. The coating film covered with a mask that can form a desired image pattern (pixel pitch of 500 μm, and line width of 50 μm) was exposed after applying an i beam thereto (100 mJ/cm²). Subsequently, the resultant was developed by using a sodium carbonate solution as a developer and rinsed with pure water, to obtain a pixel pattern-shaped structure 1208.

Subsequently, as a material of partition walls 1204, a white photosensitive composition formed of an epoxy-based resin, an acryl-based resin, a rutile-type titanium oxide, a photopolymerization initiator, and an aromatic solvent was stirred and mixed to obtain a negative resist.

Subsequently, the substrate 1201 was coated with the negative resist by using the spin coater. Thereafter, the resultant was prebaked at 80° C. for 10 minutes to obtain the coating film having a thickness of 50 μm. The coating film covered with a mask that can form a desired image pattern (pixel pitch of 500 μm, and line width of 50 μm) was exposed after applying an i beam thereto (300 mJ/cm²). Subsequently, the resultant was developed by using an alkali developer and a pixel pattern-shaped structure was obtained. Subsequently, the post baking was performed at 140° C. for 60 minutes by using a hot-air circulating drying furnace to manufacture the partition walls 1204 that perform separation into dots.

Subsequently, as illustrated in FIG. 18B, a red color filter 1209R, a green color filter 1209G, and a blue color filter 1209B were formed into patterns on areas partitioned by the partition walls 1204.

Subsequently, as illustrated in FIGS. 18C to 18E, a red phosphor layer 1221, a green phosphor layer 1222, and a blue light scattering layer 1223 were formed into patterns on the areas partitioned by the partition walls 1203 in the same manner as in Example 1.

In the process of forming the red phosphor layer 1221, first, 100 g of the dichlorobenzene solution in which 10 wt % of polystyrene was dissolved was added to 0.01 g of red phosphor Rhodamine 6G, and the resultant was heated and stirred to prepare coating liquid for forming red phosphors.

The prepared coating liquid for forming red phosphors was applied to patterns on the areas partitioned by the partition walls 1204 in a method of a dispenser. Subsequently, the resultant was heated and dried in the vacuum oven (in the condition of 200° C. and 10 mmHg) for 4 hours, so that red phosphor layer 1221 having a refractive index of 1.50 was formed into patterns (see FIG. 18C).

In the process of forming the green phosphor layer 1222, 100 g of the dichlorobenzene solution in which 10 wt % of polystyrene was dissolved was added to 0.01 g of coumarin 6, and the resultant was heated and stirred to prepare coating liquid for forming green phosphors.

The prepared coating liquid for forming green phosphors was applied into patterns on the areas partitioned by the partition walls 1204 in a method of a dispenser. Subsequently, the resultant was heated and dried in the vacuum oven (in the condition of 200° C. and 10 mmHg) for 4 hours, so that the green phosphor layer 1222 having a refractive index of 1.50 was formed into patterns (see FIG. 18D).

In the process of forming the blue light scattering layer 1223, first, 5 g of titanium oxide having an average particle diameter of 200 nm which were light scattering particles was added to 30 g of the resin “LuxPrint 8155” manufactured by Teijin DuPont Films Japan Limited, which was the binder resin, the resultant was mixed well in an automatic mortar for 30 minutes and stirred for 15 minutes by a dispersing and stirring apparatus “Filmics 40-40 type” manufactured by Primix Corporation, to obtain coating liquid for forming the blue light scattering layer.

The prepared coating liquid for forming the blue light scattering layer was applied into patterns on the areas partitioned by the partition walls 1204 in a method of a dispenser. Subsequently, the resultant was heated and dried in the vacuum oven (in the condition of 200° C. and 10 mmHg) for 4 hours, so that the blue fluorescence scattering layer having a refractive index of 1.60 was formed into patterns (see FIG. 18E).

A phosphor substrate 1240 was completed as described above.

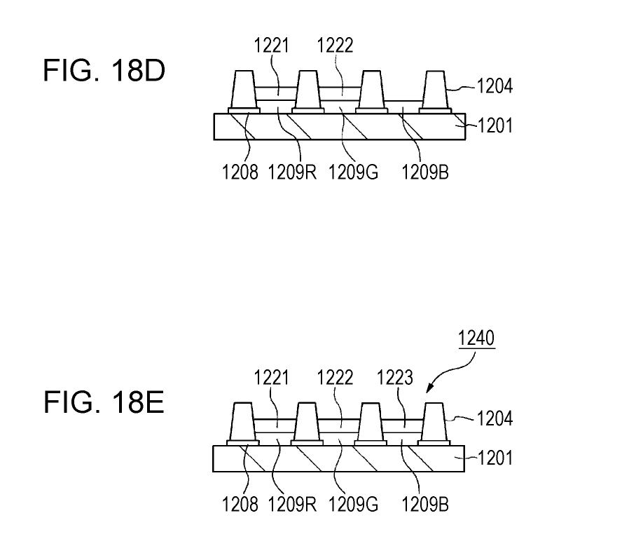

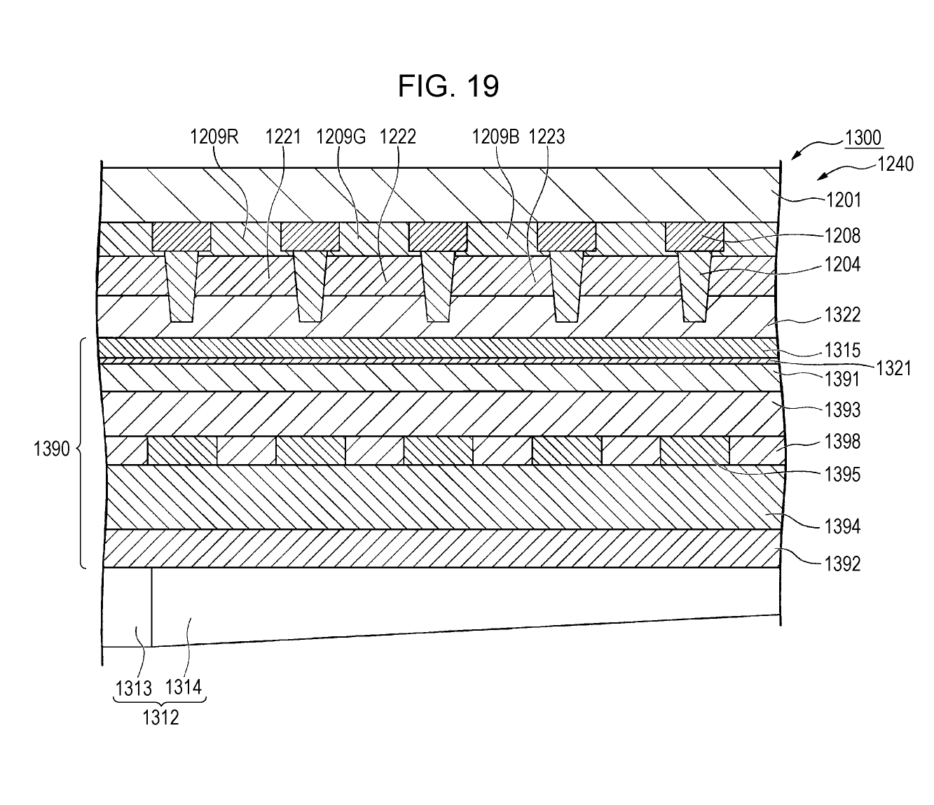

FIG. 19 is a cross-sectional view illustrating a display device 1300 according to Comparative example 3.

The display device 1300 includes a backlight 1312, a liquid crystal substrate 1390, and the phosphor substrate 1240.

The backlight 1312 includes a light source 1313 and a light guide plate 1314. As the light source 1313, a blue LED (peak wavelength 450 nm) having directivity of 10° of a half-value width was used.

The liquid crystal substrate 1390 includes a first polarizing plate 1391, a first substrate 1393, a liquid crystal layer 1398, a second substrate 1394, and a second polarizing plate 1392. The extinction ratio of the first polarizing plate 1391 and the second polarizing plate 1392 in the wavelength of equal to or more than 435 nm and equal to or less than 480 nm was 12,000. The driving method of the liquid crystal is an active matrix driving method using a TFT. The pixels of the liquid crystal substrate 1390 were partitioned by a black matrix 1395.

A band pass filter 1315 that transmits light in the blue area and reflects light in the green area to the infrared area was bonded to the first polarizing plate 1391 with a first bonding layer 1321.

The phosphor substrate 1240 manufactured by the method described above was bonded to the liquid crystal substrate 1390 provided with the band pass filter 1315 by a second bonding layer 1322. As the first bonding layer 1321 and the second bonding layer 1322, thermosetting transparent elastomer was used.

Excitation light with a wavelength of 460 nm was applied from the fluorescent layer side of the phosphor substrate, and the light extraction efficiency on the front surface of the phosphor substrate was measured by using a total luminous flux measurement system (HalfMoon manufactured by Otsuka Electronics Co., Ltd.). As the result thereof, the light extraction efficiency was 19.6%.

### Example 3-1

As a substrate 101, glass having a thickness of 0.7 mm was used. After being rinsed, the glass was subjected to 10 minutes of pure water ultrasonic washing, 10 minutes of acetone ultrasonic washing, and 5 minutes of isopropyl alcohol steam washing, and dried for 1 hour at 100° C.

As the black partition wall material, a BK resist manufactured by Tokyo Ohka Kogyo Co., Ltd. was coated by using a spin coater. Thereafter, the resultant was prebaked at 70° C. for 15 minutes to form a coating film having a thickness of 1 μm. The coating film covered with a mask that can form a desired image pattern (pixel pitch of 500 μm, and line width of 50 μm) was exposed after applying an i beam thereto (100 mJ/cm²). Subsequently, the resultant was developed by using a sodium carbonate solution as a developer and rinsed with pure water, to obtain a pixel pattern-shaped structure 102.

Subsequently, as a material of the partition walls 1204, a white photosensitive composition formed of an epoxy-based resin, an acryl-based resin, a rutile-type titanium oxide, a photopolymerization initiator, and an aromatic solvent was stirred and mixed to obtain a negative resist.

Subsequently, the substrate 1201 was coated with the negative resist by using the spin coater. Thereafter, the resultant was prebaked at 80° C. for 10 minutes to obtain the coating film having a thickness of 50 μm. The coating film covered with a mask that can form a desired image pattern (pixel pitch of 500 μm, and line width of 50 μm) was exposed after applying an i beam thereto (300 mJ/cm²). Subsequently, the resultant was developed by using an alkali developer and a pixel pattern-shaped structure was obtained. Subsequently, the post baking was performed at 140° C. for 60 minutes by using a hot-air circulating drying furnace to manufacture the partition walls 1204 that perform separation into dots.

In the same manner as in Comparative example 1, a red phosphor layer 1209R, a green phosphor layer 1209G, and a blue light scattering layer 1209B were formed into patterns on areas partitioned by the partition walls 1204.

In the process of forming the red phosphor layer 1209R, first, 100 g of the dichlorobenzene solution in which 10 wt % of polystyrene was dissolved was added to 0.01 g of red phosphor Rhodamine 6G, 40 g of hollow silica having a refractive index of 1.21 and a particle diameter of 20 nm were added, and the resultant was heated and stirred to prepare coating liquid for forming red phosphors.

The prepared coating liquid for forming the red phosphors was applied into patterns on the areas partitioned by the partition walls 1204 in a method of a dispenser. Subsequently, the resultant was heated and dried in the vacuum oven (in the condition of 200° C. and 10 mmHg) for 4 hours, so that the red phosphor layer 1209R having a refractive index of 1.50 was formed into patterns.

In the process of forming the green phosphor layer 1209G, 100 g of the dichlorobenzene solution in which 10 wt % of polystyrene was dissolved was added to 0.01 g of coumarin 6, 40 g of hollow silica having a refractive index of 1.21 and a particle diameter of 20 nm were added, and the resultant was heated and stirred to prepare coating liquid for forming green phosphors.

The prepared coating liquid for forming the green phosphors was applied into patterns on the areas partitioned by the partition walls 1204 in a method using a dispenser. Subsequently, the resultant was heated and dried in the vacuum oven (in the condition of 200° C. and 10 mmHg) for 4 hours, so that the green phosphor layer 1209G having a refractive index of 1.50 was formed into patterns.

In the process of forming the blue light scattering layer 1209B, 5 g of titanium oxide having an average particle diameter of 200 nm which were light scattering particles was added to 30 g of the resin “LuxPrint 8155” manufactured by Teijin DuPont Films Japan Limited, which was the binder resin, 10 g of hollow silica having a refractive index of 1.21 and a particle diameter of 20 nm were added, and the resultant was mixed well in an automatic mortar for 30 minutes and stirred for 15 minutes by a dispersing and stirring apparatus “Filmics 40-40 type” manufactured by Primix Corporation, to obtain coating liquid for forming the blue light scattering layer.

The prepared coating liquid for forming the blue light scattering layer was applied into patterns on the areas partitioned by the partition walls 1204 in a method of a dispenser. Subsequently, the resultant was heated and dried in the vacuum oven (in the condition of 200° C. and 10 mmHg) for 4 hours, so that the blue fluorescence scattering layer 1209B having a refractive index of 1.60 was formed into patterns.

A phosphor substrate was completed as described above.

The LED backlight 1312 according to Comparative example 3, the liquid crystal device 1390, and the band pass filter were bonded to the phosphor substrate to obtain a display device.

Finally, the excitation light of the wavelength of 460 nm was applied from the fluorescent layer side of the phosphor substrate, and the light extraction efficiency on the front surface of the phosphor substrate was measured by using a total luminous flux measurement system (HalfMoon manufactured by Otsuka Electronics Co., Ltd.). As the result thereof, the light extraction efficiency was 38.7%.

### Example 3-2

As the substrate 1201, glass having a thickness of 0.7 mm was used. After being rinsed, the glass was subjected to 10 minutes of pure water ultrasonic washing, 10 minutes of acetone ultrasonic washing, and 5 minutes of isopropyl alcohol steam washing, and dried for 1 hour at 100° C.

As the black partition wall material, a BK resist manufactured by Tokyo Ohka Kogyo Co., Ltd. was coated by using a spin coater. Thereafter, the resultant was prebaked at 70° C. for 15 minutes to form a coating film having a thickness of 1 μm. The coating film covered with a mask that can form a desired image pattern (pixel pitch of 500 μm, and line width of 50 μm) was exposed after applying an i beam thereto (100 mJ/cm²). Subsequently, the resultant was developed by using a sodium carbonate solution as a developer and rinsed with pure water, to obtain the pixel pattern-shaped structure 102.

Subsequently, as a material of the partition walls 1204, a white photosensitive composition formed of an epoxy-based resin, an acryl-based resin, a rutile-type titanium oxide, a photopolymerization initiator, and an aromatic solvent was stirred and mixed to obtain negative resist.

Subsequently, the substrate 1201 was coated with the negative resist by using the spin coater. Thereafter, the resultant was prebaked at 80° C. for 10 minutes to obtain the coating film having a thickness of 50 μm. The coating film covered with a mask that can form a desired image pattern (pixel pitch of 500 μm, and line width of 50 μm) was exposed after applying an i beam thereto (300 mJ/cm²). Subsequently, the resultant was developed by using an alkali developer and a pixel pattern-shaped structure was obtained. Subsequently, the post baking was performed at 140° C. for 60 minutes by using a hot-air circulating drying furnace to manufacture the partition walls 1204 that perform separation into dots.

In the same manner as in Comparative example 1, the red phosphor layer 1209R, the green phosphor layer 1209G, the blue light scattering layer 1209B were formed into patterns on areas partitioned by the partition walls 1204.

In the process of forming the red phosphor layer 1209R, 100 g of the toluene solution in which 10 wt % of polystyrene was dissolved was added to 0.05 g of Lumogen red F305, 40 g of hollow silica having a refractive index of 1.21 and a particle diameter of 20 nm were added, and the resultant was heated and stirred to prepare coating liquid for forming red phosphors.

The prepared coating liquid for forming the red phosphors was applied into patterns on the areas partitioned by the partition walls 1204 in a method of a dispenser. Subsequently, the resultant was heated and dried in the vacuum oven (in the condition of 200° C. and 10 mmHg) for 4 hours, so that the red phosphor layer 1209R was formed into patterns.

In the process of forming the green phosphor layer 1209G, first, 100 g of the toluene solution in which 10 wt % of polystyrene was dissolved was added to 0.05 g of Lumogen yellow F083, 40 g of hollow silica having a refractive index of 1.21 and a particle diameter of 20 nm were added, and the resultant was heated and stirred to prepare coating liquid for forming green phosphors.

The prepared coating liquid for forming the green phosphor layer was applied into patterns on the areas partitioned by the partition walls 1204 in a method of a dispenser. Subsequently, the resultant was heated and dried in the vacuum oven (in the condition of 200° C. and 10 mmHg) for 4 hours, so that the green phosphor layer 1209G was formed into patterns.

In the process of forming the blue light scattering layer 1209B, 5 g of titanium oxide having an average particle diameter of 200 nm which were light scattering particles was added to 30 g of the resin “LuxPrint 8155” manufactured by Teijin DuPont Films Japan Limited, which was the binder resin, 10 g of hollow silica having a refractive index of 1.21 and a particle diameter of 20 nm were added, the resultant was mixed well in an automatic mortar for 30 minutes and stirred for 15 minutes by a dispersing and stirring apparatus “Filmics 40-40 type” manufactured by Primix Corporation, to obtain coating liquid for forming the blue light scattering layer.

The prepared coating liquid for forming the blue light scattering layer was applied into patterns on the areas partitioned by the partition walls 1204 in a method of a dispenser. Subsequently, the resultant was heated and dried in the vacuum oven (in the condition of 200° C. and 10 mmHg) for 4 hours, so that the blue fluorescence scattering layer 1209B having a refractive index of 1.60 was formed into patterns.

A phosphor substrate was completed as described above.

The LED backlight 1312 according to Comparative example 3, the liquid crystal device 1390, and the band pass filter were bonded to the phosphor substrate to obtain a display device.

Finally, the excitation light with a wavelength of 460 nm was applied from the fluorescent layer side of the phosphor substrate, and the light extraction efficiency on the front surface of the phosphor substrate was measured by using a total luminous flux measurement system (HalfMoon manufactured by Otsuka Electronics Co., Ltd.). As the result thereof, the light extraction efficiency was 39.9%.

### INDUSTRIAL APPLICABILITY

Several aspects according to the invention can be used in the fields of phosphor substrates, display devices, and electronic apparatuses.

### REFERENCE SIGNS LIST

10 FLUORESCENT MATERIAL
11 PHOSPHOR
12 FINE PARTICLE
20 PHOSPHOR SUBSTRATE
100 DISPLAY DEVICE

1-18. (canceled)

19. An electronic apparatus comprising:
an excitation light source; and
a phosphor substrate comprising a phosphor, the phosphor being excited by first light from the excitation light source, wherein
the phosphor substrate is partitioned into a plurality of pixels, and comprises a red pixel and a green pixel, the red pixel emitting red light, the green pixel emitting green light,
at least one of the red pixel and the green pixel comprises fluorescent material, the fluorescent material comprising the phosphor and a fine particle, and
the fine particle has a refractive index lower than that of the phosphor.

20. The electronic apparatus according to claim 19, wherein
the phosphor substrate is partitioned into the plurality of pixels by a partition wall.

21. The electronic apparatus according to claim 19, wherein
the refractive index of the fine particle is higher than 1.0 and lower than 1.3.

22. The electronic apparatus according to claim 19, wherein
the fine particle is one of a porous particle and a hollow particle.

23. The electronic apparatus according to claim 19, wherein
the excitation light source is an organic electroluminescence element, organic electroluminescence element emitting one of ultraviolet light and blue light.

24. The electronic apparatus according to claim 19, wherein
the excitation light source is one of an ultraviolet light LED and a blue light LED.

25. The electronic apparatus according to claim 19, wherein
at least a portion of side surfaces of at least one of the red pixel and the green pixel is surrounded by a partition wall, the partition wall having light scattering property.

26. The electronic apparatus according to claim 19, further comprising:
a band pass filter provided between the excitation light source and the phosphor substrate, the band pass filter transmitting only second light having a specific wavelength, the band pass filter reflecting third light other than the second light.

27. The electronic apparatus according to claim 19, wherein
horizontal and vertical sizes of an opening portion of a partition wall are from 20 μm×20 μm to 500 μm×500 μm.
